(19) United States
(12) Patent Application Publication
(10) Pub. No.: US 2008/0239685 A1
(43) Pub. Date: Oct. 2, 2008

(54) CAPACITOR BUILT-IN WIRING BOARD

(76) Inventors: Tadahiko Kawabe, Gifu (JP); Masao Kuroda, Aichi (JP)

Correspondence Address: STITES & HARBISON PLLC, 1199 NORTH FAIRFAX STREET, SUITE 900, ALEXANDRIA, VA, 22314, US

(21) Appl. No.: 12/056,640

(22) Filed: Mar. 27, 2008

(30) Foreign Application Priority Data
Mar. 27, 2007 (JP) JP 2007-080509
Mar. 27, 2007 (JP) JP 2008-080510

(51) Int. Cl. H05K 7/06

(52) U.S. Cl. 361/782

(57) ABSTRACT

A wiring board is comprised of a core board, a capacitor, a conductor containing portion and a laminated wiring portion. The core board has an accommodation hole. The capacitor has a through hole therein and is accommodated in the accommodation hole. The conductor containing portion has a current supplying conductor and is disposed in the through hole so as to be surrounded by the capacitor. The laminated wiring portion includes a component mounting region in which a first connection terminal electrically connected to the current supplying conductor is provided. Further, second connection terminals are disposed so as to sandwich the first connection terminal therebetween.

### FIELD OF THE INVENTION

The present invention relates to a capacitor built-in wiring board having a structure in which a laminated wiring portion is formed on a surface of a core board and a capacitor is accommodated in the core board.

### BACKGROUND OF THE INVENTION

With recent enhancement in speed and performance of semiconductor integrated circuit devices (IC chips) used in microprocessors (CPU) of computers and the like, the number of terminals tends to increase and the pitch between terminals tends to decrease accordingly. In general, a plurality of terminals is densely arranged in an array on the bottom surface of an IC chip and the terminal group is connected to the terminal group of a motherboard in a flip chip manner. However, since the terminal group of the IC chip and the terminal group of the motherboard are greatly different to each other in pitches between the terminals, a method for manufacturing a package in which the IC chip is mounted on an IC chip mounting circuit board and mounting the package on the motherboard is employed.

Recently, there was a great need for a system having performance higher than that of a package mounted with only one microprocessor and a package mounted with a “multi chip module (MCM)” suitable for the use of computer servers or the like was suggested as an example thereof. The MCM is an electronic component in which a plurality of microprocessor chips is mounted on a relay board. An example of such an MCM is that a plurality of microprocessor chips (arithmetic circuit portion) provided in an outer peripheral portion of the MCM and a memory chip (shared circuit portion) provided in the center of the MCM and used by those microprocessor chips are mounted on the relay board.

In a wiring board constituting such a package, it is suggested to a built-in capacitor in order to reduce switching noise of an IC chip or the like. As an example of such a wiring board, a wiring board in which a capacitor is accommodated in an accommodation hole of a core board made of polymer material, and a buildup layer is formed on top and rear surfaces of the core board is disclosed (e.g., Japanese Patent Application Laid-Open (kokai) No. 2005-39243 (“Patent Document 1”) (FIG. 4 etc.)). As for the capacitor, a via array type ceramic capacitor or the like is employed.

Since the above-mentioned memory chip consumes a large amount of power supply, it is necessary to establish a current supply path for high current supply in a wiring board, when a MCM is mounted on a wiring board disclosed in Patent Document 1. However, a ceramic capacitor is disposed as close to the MCM as possible (More particularly, immediately below the MCM) in order to effectively reduce a switching noise. Further, in order to reduce the switching noise, the ceramic capacitor tends to be formed as large as possible so as to have a large capacity.

Therefore, in order to supply a high current to the memory chip in the center of the MCM, it is possible to have composition as shown, for example, in FIGS. 20 and 21. That is, ceramic capacitors 201 are provided in each microprocessor chip 203 of a MCM 202 and are disposed apart from each other, while current supplying conductors 205 are disposed under a memory chip 204 of the MCM 202. However, a mounting area for the ceramic capacitor 201 tends to be reduced because the current supplying conductors 205 occupies the certain area. As a result, the ceramic capacitor 201 cannot be formed in a large size whereby it is difficult to increase the capacity of the ceramic capacitor. Further, since the ceramic capacitors 201 having a small coefficient of thermal expansion and high rigidity cannot reliably support the MCM 202, the mechanical stress, such as heat stress, imposes to the MCM 202. Consequently, a crack or a faulty connection tends to occur in the MCM 202.

In order to solve the above-mentioned problems, there is a possibility to have the following composition in which the ceramic capacitors 201 are not disposed apart from each other and a high current is supplied to the memory chip 204 by way of bypassing the outside of the mounting area of the ceramic capacitor 201. However, since the distance of a high current supply path becomes long, resulting in increasing the resistance.

Thus, there is another possible composition in which the ceramic capacitors 201 are not disposed apart from each other and a high current is supplied to the memory chip 204 through conductors 206 in the ceramic capacitor 201. However, since the conductors 206 in the ceramic capacitor 201 are usually made of metal material (nickel or the like) having low conductivity, such a conductor is not suitable for a high current supply path.

### BRIEF SUMMARY OF THE INVENTION

The present invention has been achieved in view of the above problems of the prior art, and an object of the invention is to provide a capacitor built-in wiring board capable of supplying high current to an electronic component, increasing a capacity of a capacitor and improving a reliability of the wiring board by reducing a mechanical stress imposed on the electronic component.

A first aspect for solving the above-problems, there is provided a capacitor built-in wiring board, comprising: a core board including a core main surface, a core rear surface and an accommodation hole opening at least at the core main surface; a capacitor including a capacitor main surface, a capacitor rear surface and a through hole penetrating the capacitor main surface and the capacitor rear surface, said capacitor having a plate-like shape and being accommodated in the accommodation hole with said capacitor main surface facing the same side as the core main surface; a conductor containing portion including current supplying conductors electrically connecting the core main surface and the core rear surface, said conductor containing portion being accommodated in the through hole of the capacitor so as to be surrounded by the capacitor; a laminated wiring portion having a laminated structure in which interlayer insulating layers and conductor layers are alternately laminated on the core main surface, and including a component mounting region for mounting an electronic component; a first connection terminal being electrically connected to the current supplying conductors and being disposed in the component mounting region; and a plurality of second connection terminals being disposed in the component mounting region so as to sandwich the first connection terminal therebetween.

Thus, according to the capacitor built-in wiring board of the first aspect, since the through hole is formed in the capacitor, the conductor containing portion can be smoothly disposed in the through hole without dividing it into a small size or reducing the size of the capacitor. Therefore, a high current can be supplied through the current supplying conductors formed in the conductor containing portion and the first connection terminal to the electronic component mounted on the component mounting region where the first connection terminal is provided. Further, irrespective of the absence/presence of the conductor containing portion, it is possible to produce the capacitor having the enlarged capacitor main surface, thereby being able to increase the capacity of the capacitor. Furthermore, the electronic component mounted on the component mounting region is reliably supported by the capacitor. Thus, since the laminated wiring portion is unlikely to deform in the component mounting region, the mechanical stress imposing on the electronic component can be alleviated, thereby improving the reliability of the capacitor built-in wiring board.

The core board constituting the above-described capacitor built-in wiring board assumes a plate -like shape having, for example, the core main surface and the core rear surface located on its opposite side. Such a core board has a plurality of accommodation holes for accommodating the capacitor. These accommodation holes may be a non-through hole which is open at the core main surface, or may be a through hole which is open at both the core main surface and the core rear surface. It is noted that the capacitor may be embedded completely in the accommodation hole, or may be embedded in a state where it projects partially.

The material for forming the core board is not particularly limited, however, a preferred core board is made of a polymer material as a principal constituent. As a specific example of the polymer material for forming the core board, it is possible to cite, for example, EP resin (epoxy resin), PI resin (polyimide resin), BT resin (bismaleimide triazine resin), PPE resin (polyphenylene ether resin) or the like. In addition, it is possible to use a composite material made of these resins and glass fibers (glass woven fabrics and nonwoven glass fabrics) or organic fibers, such as polyamide fibers.

The capacitor constituting the above-described capacitor built-in wiring board assumes an atypical plate-like shape and has the capacitor main surface, a capacitor side face and a through hole which penetrates the capacitor main surface and the capacitor rear surface. The capacitor preferably assumes a generally polygonal shape, viewed in plan, with a plurality of side faces and a through hole. Examples of the polygonal shape in the plan view include a generally rectangular shape, a generally triangular shape and a generally hexagonal shape, however, the capacitor preferably assumes the generally rectangular shape in the plan view, which is an ordinary shape. In the following description, the “generally rectangular shape” does not mean a perfect rectangular shape in the plan view but a rectangle having a through hole, chamfered corner or a curved side face therein.

Examples of a cross-sectional shape of the through hole include a circular shape, a generally rectangular shape, a generally triangular shape and a generally hexagonal shape. However, the through hole preferably assumes the circular shape in the cross-sectional view. In this case, since there is no angular corner in the through hole, any stress concentration due to temperature variation on any part (corner) of the through hole is alleviated whereby the crack in the through hole can be prevented. Since an opening area of the through hole is easily made small, the dimension of the capacitor main surface can be easily enlarged to thereby increasing the capacity of the capacitor. It is noted that the through hole may be connected to an outside area of the capacitor side face through a notch, or may not be connected thereto. However, the latter has an advantage that the mechanical integrity of the capacitor is higher than that of the former composition whereby the capacitor is unlikely to deform.

Although the position of the through hole is not limited, it is preferably formed in the center of the capacitor rather than an outer peripheral portion of the capacitor. The number of through holes may be only one or two or more. In addition, when a plurality of through holes is formed in the capacitor, the diameter of the through hole is preferably smaller than the case where only one through hole is formed.

The diameter of the through hole is preferably slightly larger than a diameter of the conductor containing portion. The diameter of the through hole is preferably set to 20% or more to 50% or less of the shortest side in the sides constituting the capacitor main surface. When the diameter of the through hole is less than 20% of the length of the shortest side constituting the capacitor main surface, it becomes difficult to supply a high current through the current supplying conductors because a diameter of the current supplying conductor formed in the conductor containing portion becomes very small. On the other hand, when the diameter of the through hole is larger than 50% of the shortest side in the sides constituting the capacitor main surface, the mechanical integrity of the capacitor falls whereby the capacitor is likely to deform. Further, when the capacitor has a plurality of via conductors therein, the diameter of the through hole is preferably larger than the diameter of the via conductor, for example, preferably 5 times or more of the diameter of the via conductor in the capacitor.

As a preferable example of the capacitor, it is possible to cite a chip capacitor or a capacitor having a structure in which a plurality of inner electrode layers are laminated by sandwiching a dielectric layer therebetween, and the capacitor comprising a plurality of via conductors in the capacitor connected to the plural inner electrode layers, a plurality of surface electrodes connected to at least end portions of the via conductors in the capacitor at the capacitor main surface. It is noted that the above-described capacitor is preferably a via array type capacitor having a plurality of via conductors in the capacitor which is disposed in the form of array as a whole. In this structure, a reduction in inductance components of the capacitor is attainable and, hence, to achieve noise absorption and stabilize the power voltage. Further, it becomes easy to attain a compact size of the entire capacitor, thereby achieving a reduction in size of the entire capacitor built-in wiring board. Furthermore, high electrostatic capacity is easily attainable despite the compact size, and the more stable power supply becomes possible.

Examples of the dielectric layer constituting a capacitor include a ceramic dielectric layer, a resin dielectric layer and a dielectric layer made of ceramic-resin compound materials or the like. Sintered bodies of high temperature sintered ceramics, such as alumina, aluminium nitride, boron nitride, silicon carbide and silicon nitride are suitably used as a ceramic dielectric layer. In addition, sintered bodies of low-temperature sintered ceramics, such as a glass ceramic in which an inorganic ceramic filler such as alumina is added to borosilicate glass or borosilicate lead glass, are suitably used. In this case, it is also preferred to use a sintered body of a dielectric ceramic, such as barium titanate, lead titanate and strontium titanate, depending on the application. In the case where the sintered body of the dielectric ceramic is used, a capacitor having a large electrostatic capacity becomes easily realizable. As a resin dielectric layer, an epoxy resin and a tetrafluoroethylene resin (PTFE) containing adhesives are used suitably. Further, in the case of a dielectric layer comprised of ceramic-resin compound material, barium titanate, lead titanate, strontium titanate and the like are suitably used as a ceramic material, and a thermosetting resin, such as epoxy resin, phenol resin, urethane resin, silicone resin, polyimide resin or unsaturated polyester; a thermoplastic resin, such as polycarbonate resin, acrylic resin, polyacetal resin or polypropylene resin; and a latex, such as nitrile-butadiene rubber, styrene-butadiene rubber or fluoride rubber, are suitably used as a resin material.

Although the forms of the internal electrode layer, the via conductor in the capacitor and the surface electrode are not particularly limited, a metallized conductor is preferable when the dielectric layer is, for example, a ceramic dielectric layer. The metallized conductor is formed in such a manner that a conductive paste containing metallic powder is applied with the conventionally known method, such as a metallize printing, and thereafter fire the thus-printed paste. When forming the metallized conductor and the ceramic dielectric layer with a simultaneous firing method, the metallic powder in the metallized conductor is required to have a higher melting point than the firing temperature of the ceramic dielectric layer. For example, when the ceramic dielectric layer is comprised of so-called high temperature sintered ceramic (e.g., alumina or the like), nickel (Ni), tungsten (W), molybdenum (Mo), manganese (Mn), or an alloy containing any one of them may be selected as metallic powder contained in the metallized conductor. When the ceramic dielectric layer comprised of so-called low-temperature sintered ceramic (e.g., glass ceramic or the like), copper (Cu), silver (Ag) or the like, or an alloy containing one of them may be selected as metallic powder contained in the metallized conductor.

In the conductor containing portion constituting the above-mentioned capacitor built-in wiring board, a current supplying conductor is formed so as to electrically connect the core rear surface to the core main surface, and the conductor containing portion is disposed in the through hole of the capacitor so as to be surrounded by the capacitor. The conductor containing portion may be or may not be completely surrounded by the capacitor within the through hole of the capacitor. Although the material for forming the conductor containing portion is not particularly limited, a preferable conductor containing portion is made of a polymer material as a principal constituent. As specific examples of the polymer material for forming conductor containing portion, it is possible to cite, for example, an epoxy resin, polyimide resin, bismaleimide triazine resin, polyphenylene ether resin or the like. In addition, it is possible to use a composite material of these resins and glass fibers (a glass woven fabric and a nonwoven glass fabric) or organic fibers, such as polyamide fibers. The conductor containing portion is preferably made of the same material as the core board. In this way, as for a material for forming the conductor containing portion, it is not necessary to prepare a different material other than the material for forming the core board. Thus, the capacitor built-in in wiring board can be manufactured cost-effective. Further, the conductor containing portion is easily formed as a part of the core board.

The conductor containing portion may be a part of the core board, or may be formed as a separate body from the core board. When the conductor containing portion is a part of the core board, as for a material for forming the conductor containing portion, it is not necessary to prepare a different material other than the material for forming the core board. Thus, the capacitor built-in wiring board can be manufactured cost-effective. On the other hand, when the conductor containing portion is formed as a separate body from the core board, design flexibility of the conductor containing portion is improved because the conductor containing portion can be made into a completely different composition to that of the core board.

Although the material for forming the current supplying conductor is not particularly limited, preferred materials are cited from, for example, copper, copper alloy, nickel, nickel alloy, tin, tin alloy, conductive resin paste or the like. As for the method of forming the current supplying conductor, a plating method is preferable because it is easy to conduct and is reasonable. However, it is also possible to adopt a method, such as sputtering, CVD, or vacuum deposition, besides the plating method. When the conductive resin paste is used for the material for forming the current supplying conductor, it is preferable to use a printing method for filling a hole which opens at both the core main surface and the core rear surface.

The current supplying conductor is preferably made of a metal material having higher conductivity than that of the plural via conductors in the capacitor. When the current supplying conductor is made of a metal material having the same conductivity as that of the via conductors in the capacitor or made of a material having lower conductivity than that of the via conductors in the capacitor, it is meaningless (no improvement in conductivity) to use the current supplying conductor as a high current supply path instead of the via conductors in the capacitor. When the via conductor in the capacitor is, for example, made of nickel, the current supplying conductor is preferably made of copper, silver or the like which are the metal material having higher conductivity than nickel, more preferably, the use of copper is advantageous considering its reasonable cost.

Further, it is preferable that the current supplying conductor constitutes no signal wiring for sending a signal to electronic components. In this way, since the only wiring for supplying electric current to the conductor containing portion can be formed, many current supplying conductors (or current supplying conductors having large diameter) can be formed in the conductor containing portion, while avoiding an enlargement of the conductor containing portion. When the current supplying conductor constitutes a signal wiring, the current supplying conductor (signal wiring) and the capacitor are disposed close to each other. In this case, electromagnetic wave generated from the signal wiring is taken into the conductors in the capacitor as a noise and is likely to cause a failure. As a result, adequate current supply is possibly interfered. Further, since the electromagnetic wave generated from the conductors in the capacitor is taken into the signal wiring as a noise, it is likely to cause a failure.

The laminated wiring portion constituting the above-mentioned mentioned capacitor built-in wiring board has a structure in which interlayer insulating layers made of a polymer material and conductor layers are laminated, and a component mounting region for mounting electronic components is formed thereon. A first connection terminal electrically connected to the current supplying conductor is disposed in the component mounting region, and a plurality of second connection terminals is disposed so as to sandwich the first connection terminal therebetween. It is noted that there is a large difference in the terminal pitch between a group of terminals on the electronic components and a group of terminals on the capacitor, however, by providing the laminated wiring portion, the electronic components and the capacitor can be easily connected through the plural second connection terminals. Further, although the laminated wiring portion is formed only on the core main surface, another laminated wiring portion having the same structure as the above-mentioned laminated wiring portion may be formed on the core rear surface. In this away, the electric circuit can be formed not only on the laminated wiring portion formed on the core main surface, but also on the other laminated wiring portion formed on core rear surface. As a result, further multifunction of the capacitor built-in wiring board is attainable.

A current supplying connection pad having a larger diameter than that of the current supplying conductor is preferably provided on an end of the current supplying conductor. In this way, the current supplying conductor and the first connection terminal are reliably connected to each other, compared to the case where the current supplying conductor is directly connected to the first connection terminal. Further, since the diameter of the current supplying connection pad is larger than that of the current supplying conductor, resistance in a current supply path constituted by the current supplying conductor and the first connection terminal can be lowed. Furthermore, since the diameter of the current supplying connection pad is larger than that of the current supplying conductor, the current supplying connection pads and the via conductors can be reliably connected even though a position for forming a via conductor is slightly misaligned when forming the via conductor on the current supplying connection pad.

In consideration of insulation, heat resistance, moisture resistance of the interlayer insulating layer, preferred polymer materials for forming the interlayer insulating layer are cited from, for example, a thermosetting resin, such as epoxy resin, phenol resin, urethane resin, silicone resin, polyimide resin; and a thermoplastic resin, such as polycarbonate resin, acrylic resin, polyacetal resin or polypropylene resin. In addition, a composite material of these resin and glass fibers (glass woven fabric or non-woven glass fabric) or organic fibers, such as polyamide fibers, or alternatively, a resin-resin composite material formed in such a manner that thermosetting resin, such as epoxy resin, is impregnated with three dimensional mesh-like fluorocarbon resin base material, such as continuous porosity PTFE.

Although a material for forming the conductor layer is not particularly limited, preferred materials are, for example, copper, copper alloy, nickel, nickel alloy, tin, tin alloy, conductive resin paste or the like. Materials for forming the first connection terminal, the second connection terminals and the current supplying connection pad are not particularly limited, however, the same material as that of the above-mentioned conductor layer is preferably used. In this way, the first connection terminal, the second connection terminals and the current supplying connection pad can be simultaneously formed with the formation of the laminated wiring portion. More particularly, the preferred material for forming the conductor layer, the first connection terminal, the second connection terminals and the current supplying connection pad is copper having low resistance.

The first connection terminal (and the current supplying connection pad) is preferably made of a metal material having the same conductivity as the metal material of the current supplying conductor, or made of a metal material having higher conductivity than that of the current supplying conductor. When the first connection terminal (and the current supplying connection pad) is made of a metal material having a lower conductivity than a material of the current supplying conductor, high current cannot be efficiently supplied to the electronic components because resistance of the current supply path, which is comprised of the current supplying conductor (and the current supplying connection pad) and the first connection terminal, becomes high.

As specific examples of an electronic component, it is possible to cite, an integrated circuit element (IC chip) used as a microprocessor of a computer or the like, a multi-chip module (MCM) in which a plurality of microprocessor chips is mounted on a relay board, a MEMS (Micro Electro Mechanical System) element manufactured in a semiconductor manufacturing process. As an example of the MCM, it is possible to cite a MCM having a structure in which a plurality of microprocessor chips (arithmetic circuit portion) and a memory chip (shared circuit portion), which requires larger current supply than the current supply required by the plurality of microprocessor chips and is shared by the microprocessor chips, are mounted on a relay board.

The above-mentioned electronic component is mounted on the component mounting region with, for example, a flip chip connection. The “component mounting region” means a region in the surface of the laminated wiring portion on which a group of terminal pads is disposed.

Further, a plurality of second connection terminals is electrically connected to a plurality of arithmetic circuit portions, respectively, provided in the electronic components. The first connection terminal is shared by the plural arithmetic circuit portions, and is preferably electrically connected to the shared circuit portion, which requires larger current supply than the current supply required by the plurality of arithmetic circuit portions. In this way, arithmetic circuit portions can be reliably connected to the capacitor through the second connection terminal. Furthermore, the shared circuit portion can be reliably connected to the current supplying conductor through the first connection terminal.

A second aspect for solving the above-problems, there is provided a capacitor built-in wiring board, comprising: a core board including a core main surface, a core rear surface, a conductor containing portion including current supplying conductors electrically connecting the core main surface and the core rear surface, and a plurality of accommodation holes opening at least at the core main surface and disposed so as to sandwich the conductor containing portion; a plurality of capacitors each including a capacitor main surface, a capacitor rear surface and a capacitor side face, each capacitor having a plate-like shape with a notch in the capacitor side face and being accommodated in the plurality of accommodation holes with the notch facing the conductor containing portion; and a laminated wiring portion having a laminated structure in which interlayer insulating layers and conductor layers are alternately laminated on the core main surface, and including a component mounting region for mounting an electronic component; a first connection terminal being electrically connected to the current supplying conductors and being disposed in the component mounting region; and a plurality of second connection terminals being disposed in the component mounting region so as to sandwich the first connection terminal.

Therefore, according to the capacitor built-in wiring board of the second aspect, high current can be supplied to an electronic component mounted on the component mounting region where the first connection terminal is disposed through the current supplying conductors and the first connection terminal. Since the plurality of capacitors are accommodated in the accommodation holes, respectively, with the notches facing the conductor containing portion, each capacitor is not necessarily disposed apart from each other so as to avoid the conductor containing portion. Further, irrespective of the absence/presence of the conductor containing portion, it is possible to produce the capacitor having the enlarged capacitor main surface, thereby being able to increase the capacity of the capacitor. Furthermore, the electronic component mounted on the component mounting region is reliably supported by the capacitor. Thus, since the laminated wiring portion is unlikely to deform in the component mounting region, the mechanical stress imposing on the electronic component can be alleviated, thereby improving the reliability of the capacitor built-in wiring board.

In the conductor containing portion constituting the above-mentioned capacitor built-in wiring board, the current supplying conductors are formed so as to electrically connect the core rear surface to the core main surface, and the conductor containing portion is formed in the core board. Although the material for forming the conductor containing portion is not particularly limited, a preferable conductor containing portion is made of a polymer material as a principal constituent. As specific examples of the polymer material for forming conductor containing portion, it is possible to cite, for example, an epoxy resin, polyimide resin, bismaleimide triazine resin, polyphenylene ether resin or the like. In addition, it is possible to use a composite material of these resins and glass fibers (a glass woven fabric and a nonwoven glass fabric) or organic fibers, such as polyamide fibers. The conductor containing portion is preferably made of the same material as the core board. In this way, as for a material for forming the conductor containing portion, it is not necessary to prepare a different material other than the material for forming the core board. Thus, the capacitor built-in wiring board can be manufactured cost-effective. Further, the conductor containing portion and the core board can be easily formed integrally.

It is preferable that the current supplying conductor constitutes no signal wiring for sending a signal to electronic components. When the current supplying conductor constitutes the signal wiring, the current supplying conductor (signal wiring) and the capacitor are disposed close to each other. In this case, electromagnetic wave generated from the signal wiring is taken into the conductors in the capacitor as a noise and may cause a failure. As a result, adequate current supply is likely to be interfered. Further, since the electromagnetic wave generated from the conductors in the capacitor is taken into the signal wiring as a noise, it is likely to cause a failure.

The capacitor constituting the above-described capacitor built-in wiring board assumes an atypical plate-like shape and has the capacitor main surface, a capacitor side face, the capacitor rear surface and a notch in the capacitor side face. The capacitor preferably assumes a generally polygonal shape in the plan view with a plurality of side faces and the notch. Examples of the polygonal shape in the plan view includes a generally rectangular shape, a generally triangular shape and a generally hexagonal shape. More particularly, the capacitor preferably assumes the generally rectangular shape in the plan view. In the following description, the “generally rectangular shape” does not mean a perfect rectangular shape in the plan view but a rectangle having a notch, a chamfered corner or a curved side face therein. Furthermore, the shape of the notch as viewed from the capacitor main surface side may assume a generally “V” shape or a generally “U” shape or the like.

The above-mentioned electronic component is mounted on the component mounting region with, for example, a flip chip connection. Although the number of arithmetic circuit portion may be two or more, the number of arithmetic circuit portion is preferably the same number as that of, for example, the capacitor. Constituting this way, all the arithmetic circuit potions can be electrically connected to the capacitors, respectively. The “component mounting region” means a region in the surface of the laminated wiring portion on which a group of terminal pads is disposed.

Other features and advantages of the invention will be set forth in, or apparent from, the detailed description of preferred embodiments of the invention found below.

### BRIEF DESCRIPTION OF THE SEVERAL VIEWS OF THE DRAWINGS

FIG. 1 is a side sectional view of a capacitor built-in wiring board according to a first exemplary embodiment of the invention.

FIG. 2 is a side elevational view of an exemplary multi-chip module (“MCM”).

FIG. 3 is a top plan view of the MCM of FIG. 2.

FIG. 4 is a diagram of the capacitor built-in wiring board of FIG. 1 showing a positional relation between a core board, a conductor containing portion, a ceramic capacitor and a MCM.

FIG. 5 is a side sectional view of a ceramic capacitor of the capacitor built-in wiring board of FIG. 1.

FIG. 6 is a top plan view of a capacitor main surface of the ceramic capacitor of FIG. 5.

FIG. 7 is a top sectional view of the ceramic capacitor of FIG. 5, showing an inner layer of the ceramic capacitor.

FIG. 8 is a top sectional view of the ceramic capacitor of FIG. 5, showing an inner layer of the ceramic capacitor.

FIG. 9 is a side sectional view of the capacitor built-in wiring board according to the first exemplary embodiment at a step of a method for manufacturing the capacitor built-in wiring board.

FIG. 10 is a side sectional view of the capacitor built-in wiring board according to the first exemplary embodiment at a another step of a method for manufacturing the capacitor built-in wiring board.

FIG. 11 is a side sectional view of the capacitor built-in wiring board according to the first exemplary embodiment at a another step of a method for manufacturing the capacitor built-in wiring board.

FIG. 12 is a side sectional view of the capacitor built-in wiring board according to the first exemplary embodiment at a another step of a method for manufacturing the capacitor built-in wiring board.

FIG. 13 is a side sectional view of the capacitor built-in wiring board according to the first exemplary embodiment at a another step of a method for manufacturing the capacitor built-in wiring board.

FIG. 14 is a side sectional view of the capacitor built-in wiring board according to the first exemplary embodiment at a another step of a method for manufacturing the capacitor built-in wiring board.

FIG. 15 is a side sectional view of the capacitor built-in wiring board according to the first exemplary embodiment at a another step of a method for manufacturing the capacitor built-in wiring board.

FIG. 16 is a top plan view of a capacitor built-in wiring board according to a variation of the first exemplary embodiment, showing a positional relation between a core board, a conductor containing portion, a ceramic capacitor and a MCM.

FIG. 17 is a side sectional view of the capacitor built-in wiring board of FIG. 16, at a step of a method for manufacturing the capacitor built-in wiring board

FIG. 18 is a side sectional view of the capacitor built-in wiring board of FIG. 16, at a step of a method for manufacturing the capacitor built-in wiring board.

FIG. 19 is a side sectional view of a capacitor built-in wiring board according to another variation of the first exemplary embodiment of the invention.

FIG. 20 is a side sectional view of a wiring board according to the prior art.

FIG. 21 is a diagram of a prior art wiring board showing a positional relation between a core board, a conductor containing portion, a ceramic capacitor and a MCM.

FIG. 22 is a side sectional view of a capacitor built-in wiring board according to a second exemplary embodiment of the present invention

FIG. 23 is a diagram showing a positional relation between a core board (a conductor containing portion), a ceramic capacitor and a MCM according to the second exemplary embodiment.

FIG. 24 is a top plan view showing the core board (conductor containing portion) according to the second exemplary embodiment.

FIG. 25 is a side sectional view showing a ceramic capacitor according to the second exemplary embodiment.

FIG. 26 is a top sectional view of the ceramic capacitor of FIG. 25, taken along line A-A in FIG. 25.

FIG. 27 is a top sectional view of the ceramic capacitor of FIG. 25, taken along line B-B in FIG. 25.

FIG. 28 is a side sectional view showing another ceramic capacitor according to the second embodiment.

FIG. 29 is a side sectional view of the capacitor built-in wiring board according to the second embodiment at a step of a method for manufacturing the capacitor built-in wiring board.

FIG. 30 is a side sectional view of the capacitor built-in wiring board according to the second embodiment at another step of a method for manufacturing the capacitor built-in wiring board.

FIG. 31 is a side sectional view of the capacitor built-in wiring board according to the second embodiment at another step of a method for manufacturing the capacitor built-in wiring board.

FIG. 32 is a side sectional view of the capacitor built-in wiring board according to the second embodiment at another step of a method for manufacturing the capacitor built-in wiring board.

FIG. 33 is a side sectional view of the capacitor built-in wiring board according to the second embodiment at another step of a method for manufacturing the capacitor built-in wiring board.

FIG. 34 is a diagram showing a positional relation between a core board (a conductor containing portion), a ceramic capacitor and a MCM according to a variation of the second exemplary embodiment of the invention.

### DETAILED DESCRIPTION OF EXEMPLARY EMBODIMENTS OF THE INVENTION

Hereafter, a first embodiment for carrying out a capacitor built-in wiring board according to the present invention will be described in detail with reference to the drawings.

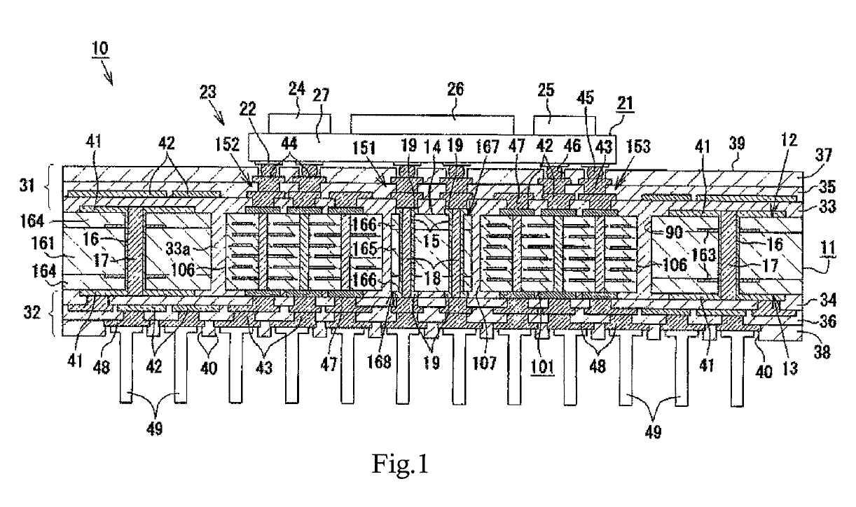

As shown in FIG. 1, a capacitor built-in wiring board 10 (hereinafter referred to as a “wiring board”) in accordance with the first embodiment is a wiring board for mounting an electronic component, and comprising: a core board 11 assuming a generally rectangular shape, a first buildup layer 31 (laminated wiring portion) formed on a core main surface 12 (upper surface in FIG. 1) of the core board 11 and a second buildup layer 32 formed on a core rear surface 13 (lower surface in FIG. 1) of the core board 11.

The first buildup layer 31 formed on the core main surface 12 of the core board 11 has a structure in which two resin insulating layers 33 and 35 (hereinafter referred to as an interlayer insulating layer) made of thermosetting resin (epoxy resin) and a conductor layer 42 made of copper are alternately laminated. Via conductors 43 are formed in plural locations in the second resin insulating layer 35. A lower end of each via conductor 43 is connected to the conductor layer 42 formed on a surface of the resin insulating layer 33. An upper end of each via conductor 43 is connected to the conductor layer 42 formed on a surface of the resin insulating layer 35. Terminal pads 44 are formed in plural locations on the surface of the second resin insulating layer 35 in the form of array. Further, the surface of the resin insulating layer 35 is entirely covered with a solder resist 37. Opening portion 46 to which the terminal pads 44 are exposed is formed on a predetermined location of the solder resist 37. A plurality of solder bumps 45 is disposed on the surfaces of the terminal pad 44, respectively. Each solder bump 45 is electrically connected to a surface connection terminal 22 of a multi-chip module (hereinafter referred to as “MCM”), which is an electronic component. In addition, a region comprised of each terminal pad 44 and each solder bump 45 serves as a component mounting region 23 for mounting the MCM 21. The component mounting region 23 is formed on a surface 39 of the first buildup layer 31.

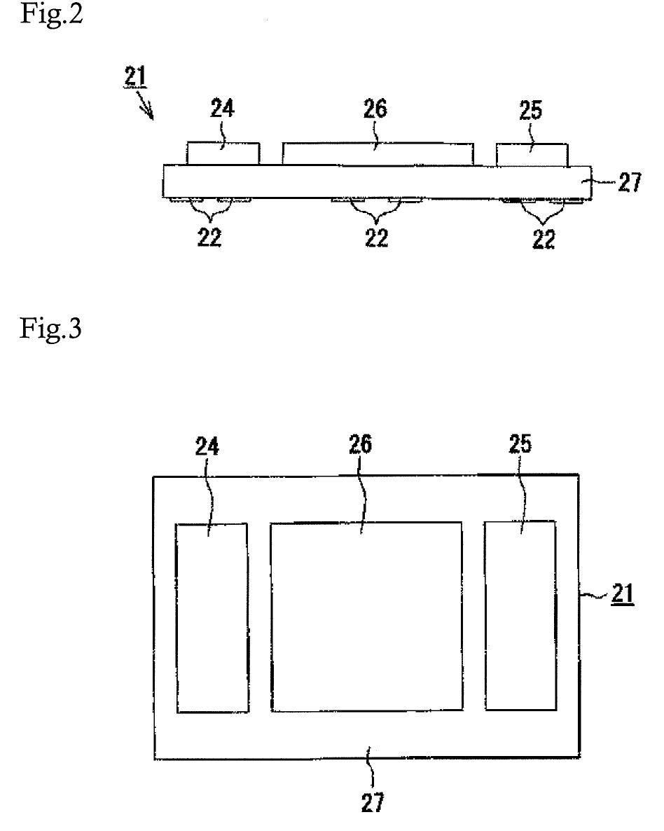

As shown in FIGS. 1 to 3, the MCM 21 of first embodiment assumes a generally rectangular form as seen from the plane view with the size of 25 mm (long)×28 mm (wide). The MCM 21 has a structure in which two microprocessor chips 24 and 25 (arithmetic circuit portions) and a memory chip 26 (a shared circuit portion) on a rectangle plate-like relay board 27. The relay board 27 is comprised of a plurality of surface connection terminals 22 provided on a lower surface of the relay board, a first conductor portion (not illustrated) which connects the surface connection terminals 22 and the memory chip 26, a second conductor portion (not illustrated) which connects the surface connection terminal 22 and the microprocessor chips 24 and 25. Each microprocessor chip 24 and 25 assumes a rectangular plate-like shape and is disposed in a peripheral portion of the relay board 27 so as to sandwich the memory chip 26. Each microprocessor chip 24 and 25 is a circuit portion for performing various operations. On the other hand, the memory chip 26 assumes a rectangular plate-like shape and is disposed in the center of the relay board 27. The memory chip 26 is a shared circuit portion used by the microprocessor chips 24, 25 for memorizing the operation results of each microprocessor chip 24, 25. It is noted that the memory chip 26 requires larger electric current supply than that required by the microprocessor chips 24, 25.

As shown in FIG. 1, the second buildup layer 32 formed on the core rear surface 13 of the core board 11 is substantially identical to that of the first buildup layer 31. That is, the second buildup layer 32 has a structure in which two resin insulating layers 34 and 36 (hereinafter referred to as an interlayer insulating layer) made of thermosetting resin (epoxy resin) and the conductor layer 42 are alternately laminated. Via conductors 47 are formed in plural locations in the first resin insulating layer 34. A lower end of each via conductor 47 is electrically connected to the conductor layer 42 formed on the surface of the resin insulating layer 34. The via conductors 43 are formed in plural locations in the second resin insulating layer 36. Further, BGA pads 48 electrically connected to the conductor layer 42 through the via conductors 43 are formed in a lattice pattern on a portion serving as a lower end of each via conductor 43 of the lower surface of the resin insulating layer 36. Moreover, the lower surface of the resin insulating layer 36 is almost entirely covered with a solder resist 38. Opening portions 40 to which the BGA pads 48 are exposed are formed in the predetermined locations of the solder resist 38. A plurality of pins 49 for electrically connecting to a motherboard (not illustrated) is disposed on the surfaces of the BGA pads 48, respectively. Then, the wiring board 10 is mounted on the motherboard (not illustrated) through each pin 49.

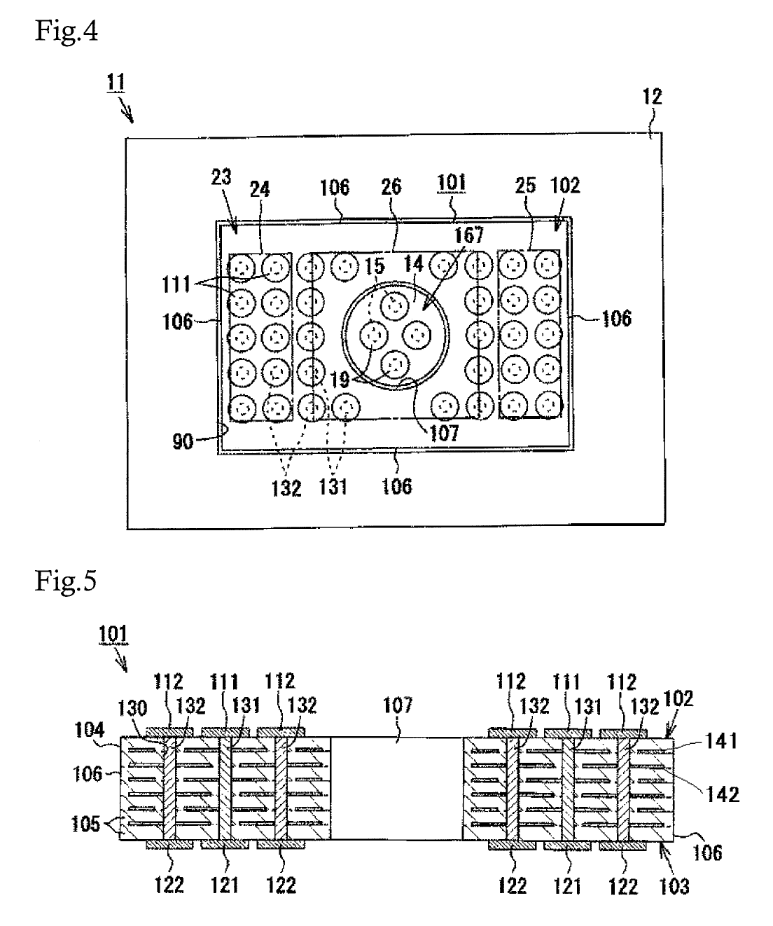

As shown in FIGS. 1 and 4, the core board 11 of the first embodiment assumes a generally rectangular plate-like shape as seen from the plane view with the size of 50.0 mm long×50.0 mm wide×1.0 mm thick. The core board 11 is comprised of a substrate 161 made of glass epoxy, a sub-substrate 164 made of epoxy resin to which inorganic fillers, such as silica filler, are added and formed on an upper surface and a lower surface of the substrate 161 and a conductor layer 163 made of copper and formed on the upper surface and the lower surface of the substrate 161. Further, the core board 11 includes a plurality of copper-made through hole conductors 16 penetrating the core main surface 12, the core rear surface 13 and the conductor layer 163. The through hole conductor 16 is for electrically connecting the core main surface 12 and the core rear surface 13 of the core board 11, as well as being connected to the conductor layer 163. It is noted that the inside of the through hole conductor 16 is filled up with a plugging body 17, such as an epoxy resin. Further, conductor layers 41 made of copper are formed on the core main surface 12 and the core rear surface 13 of the core board 11 so as to be electrically connected to the through hole conductors 16.

As shown in FIGS. 1 and 4, a conductor containing portion 14 is provided in the center of the core board 11. The conductor containing portion 14 of the first embodiment assumes a shape without any angle as seen from the plane view (i.e., a circular shape). A diameter of the conductor containing portion 14 is preferably 5.0 mm or more to 15 mm or less, and it is set to 11.0 mm in the first embodiment. The thickness of the conductor containing portion 14 is set to 1.0 mm. The conductor containing portion 14 is formed as a separate body from the core board 11 and is comprised of a first substrate 165 made of the same material as the substrate 161 (glass epoxy), and a second substrate 166 made of the same material as the sub substrate 164 (epoxy resin which includes inorganic fillers, such as a silica filler). Further, the conductor containing portion 14 includes a plurality of copper-made current supplying conductors 15 (four in the first embodiment) is formed so as to penetrated the core main surface 12 and the core rear surface 13. The current supplying conductor 15 is a through hole conductor for electrically connecting the core main surface 12 and the core rear surface 13 of the core board 11. The inside of the current supplying conductor 15 is filled with a plugging body 18, such as an epoxy resin.

As shown in FIGS. 1 and 4, current supplying connection pads 19 made of copper are formed so as to project from a main surface 167 and a rear surface 168 of the conductor containing portion 14. The current supplying connection pad 19 provided on the main surface 167 of the conductor containing portion 14 is directly connected to an end of the current supplying conductor 15 at the main surface 167. Further, the current supplying connection pad 19 provided on the rear surface 168 of the conductor containing portion 14 is directly connected to an end of the current supplying conductor 15 at the rear surface 168. The current supplying connection pad 19 has a disc-like shape, and an axis of the current supplying connection pad 19 is coaxially formed with the center of the current supplying conductor 15. The diameter of the current supplying connection pad 19 is larger than the diameter of the current supplying conductor 15 (about 100 micrometers), and it is set to about 500 micrometers in the first embodiment. The thickness of the current supplying connection pad 19 is, for example, 50 micrometers equal to the thickness of the conductor layer 41. The current supplying connection pad 19 provided on the main surface 167 of the conductor containing portion 14 is connected to the via conductor 47 formed in the resin insulating layer 33. The current supplying connection pad 19 provided on the rear surface 168 of the conductor containing portion 14 is connected to the via conductor 47 formed in the resin insulating layer 34.

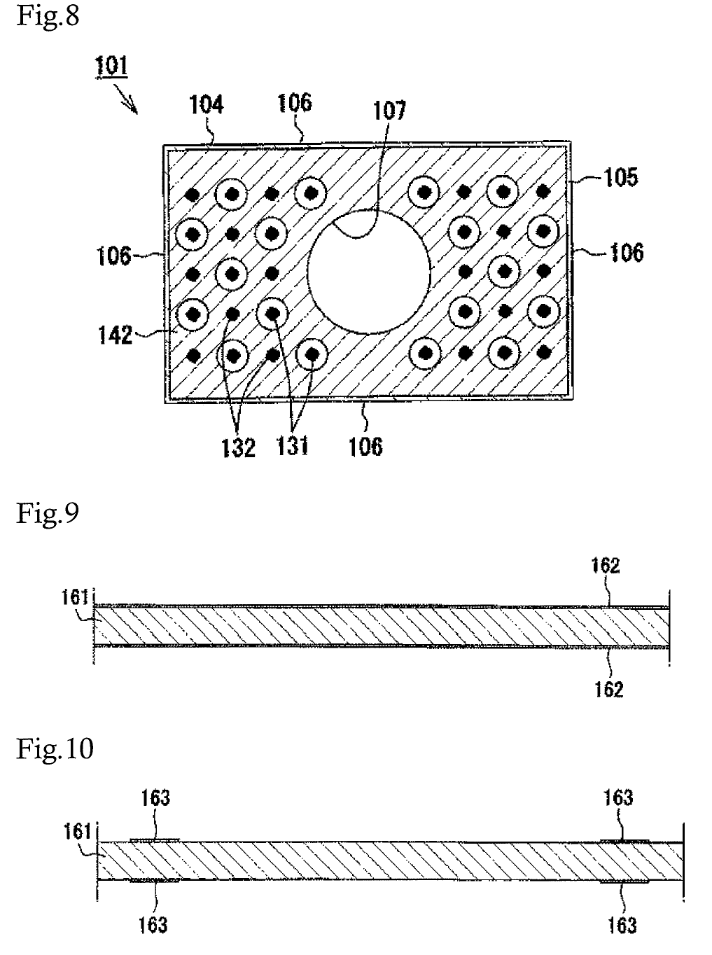

As shown in FIGS. 1 and 4, the core board 11 has an accommodation hole 90, as seen from the plane view, which opens at each center portion of the core main surface 12 and the core rear surface 13. That is, the accommodation hole 90 is a through-hole. As shown in FIGS. 5 to 8, a ceramic capacitor 101 is accommodated in the accommodation hole 90 in an embedded state. In addition, the ceramic capacitor 101 is accommodated with its capacitor main surface 102 facing the same side as the core main surface 12 of the core board 11. The ceramic capacitor 101 in the first embodiment assumes a plate-like form with the size of 25.0 mm long×25.0 mm wide×0.8 mm thick. In the core board 11, the ceramic capacitor 101 is disposed in a region immediately below the component mounting area 23. The dimension of the component mounting area 23 (an area of the region where the surface connection terminals 22 of the MCM are formed on) is equal to the capacitor main surface 102 of the ceramic capacitor 101. Thus, the component mounting area 23, as viewed in the thicknesswise direction of the ceramic capacitor 101, is disposed within the capacitor surface 102 of the ceramic capacitor 101. More particularly, as shown in FIG. 4, the microprocessor chips 24 and 25 of the MCM 21 are disposed on the capacitor main surface 102 of the ceramic capacitor 101. Further, the memory chip 26 of the MCM 21 is disposed in an upward direction of the main surface 167 of the conductor containing portion 14 so that the memory chip 26 covers the main surface 167 of the conductor containing portion 14 and the capacitor main surface 102 of the ceramic capacitor 101.

As shown in FIGS. 1 and 4, a gap between an inner face of the accommodation hole 90 and a capacitor side face 106 of the ceramic capacitor 101, and a gap between an inner wall surface of the through hole 107 of the ceramic capacitor 101 and a side face of the conductor containing portion 14 is filled with a filler 33a which is a part of lowermost resin insulating layer 33 attaching to the core main surface 12. The filler 33a has a function of fixing the ceramic capacitor 101 and the conductor containing portion 14 to the core board 11. The ceramic capacitor 101 includes a tapered portion at each four corners thereof with a radius of 0.55 mm or more (0.6 mm in the first embodiment). As a result, when the filler 33a deforms due to a temperature variation, the stress concentration to the corners of ceramic capacitor 101 can be alleviated, thereby preventing the occurrence of cracks in the filler 33a.

As shown in FIGS. 5 to 8, the ceramic capacitor 101 assumes an atypical plate-like shape in which the circular shaped through hole 107, as viewed in the cross section, penetrates the capacitor main surface 102 and the capacitor rear surface 103. The through hole 107 is formed in the center of the ceramic capacitor 101. In the first embodiment, the diameter of the through hole 107 is 15.0 mm. That is, the diameter of the through hole 107 is slightly larger than that of the conductor containing portion 14. The diameter of the through hole 107 is set to about 60% of the shortest length of the side, which constitutes the capacitor main surface 102, (the lateral length of the ceramic capacitor 101). Further, the diameter of the through hole 107 is 150 times of the diameter of the via conductor in the capacitor 131, 132 (100 micrometers). Furthermore, the conductor containing portion 14 is accommodated in the through hole 107 of the ceramic capacitor 101. Thus, the conductor containing portion 14 is disposed so as to be completely surrounded by the ceramic capacitor 101 in the through hole 107.

The ceramic capacitor 101 according to the first embodiment is so-called “a via array type ceramic capacitor”. A ceramic sintered body 104 comprising the ceramic capacitor 101 has the capacitor main surface 102 (upper surface in FIG. 1), the capacitor rear surface 103 (lower surface in FIG. 1) and four capacitor side faces 106 (right and left side faces in FIG. 1).

As shown in FIG. 5, the ceramic sintered body 104 has a structure in which a power supplying inner electrode layer 141 and a grounding inner electrode layer 142 are alternately laminated by sandwiching a ceramic dielectric layer 105. The ceramic dielectric layer 105 is comprised of a sintered body of barium titanate, i.e., a kind of high-dielectric-constant ceramic, and functions as a dielectric (insulator) between the power supplying inner electrode layer 141 and the grounding inner electrode layer 142. The power supplying inner electrode layer 141 and the grounding inner electrode layer 142 are comprised mainly of nickel and are alternately disposed inside the ceramic sintered body 104.

As shown in FIGS. 5-8, a plurality of via holes 130 are formed in the ceramic sintered body 104 in the ceramic capacitor 101. These via holes 130 penetrate the ceramic sintered body 104 in its thicknesswise direction, and are disposed on the entire surface of the ceramic sintered body 104 in the form of an array. In each via hole 130, a plurality of via conductors 131, 132 in the capacitor comprised mainly of nickel are formed so as to communicate between the capacitor main surface 102 and the capacitor rear surface 103 of the ceramic sintered body 104. Thus, the current supplying conductor 15 (see FIG. 1) is made of a metal martial (copper) with better conductivity than that the via conductor 131, 132 in the capacitor. Each power supplying via conductor 131 in the capacitor penetrates each power supplying inner electrode layer 141 so as to electrically connect therebetween. Each grounding via conductor 132 penetrates each grounding inner electrode layer 142 so as to electrically connect therebetween. Each power supplying via conductor 131 and each grounding via conductor 132 are disposed in the form of an array as a whole. Notably, for explanatory purposes, the via conductors 131, 132 are illustrated by 5×8 in rows (or 5×6 in rows), however, the actual array has more rows.

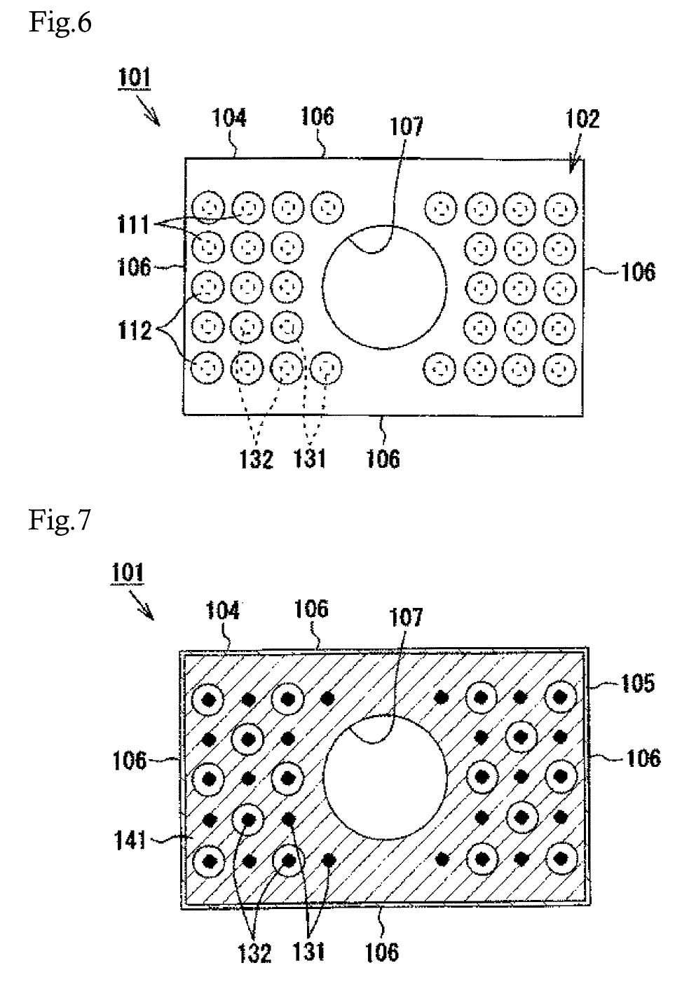

As shown in FIGS. 5 and 6, a plurality of main surface side power supplying electrodes 111 and a plurality of main surface side grounding electrodes 112 are formed on the capacitor main surface 102 of the ceramic sintered body 104 of the ceramic capacitor 101 so as to project from the capacitor main surface 102. Although each main surface side grounding electrode 112 is individually formed on the capacitor main surface 102, it may be integrally formed. The main surface side power supplying electrodes 111 are directly connected to the end faces of the plural power supplying via conductors 131 at the capacitor main surface 102. The main surface side grounding electrodes 112 are directly connected to the end faces of the plural grounding via conductors 132 at the capacitor main surface 102.

Also, a plurality of rear surface side power supplying electrode terminals 121 and a plurality of rear surface side grounding electrodes 122 are formed on the capacitor rear surface 103 of the ceramic sintered body 104 of the ceramic capacitor 101 so as to project from the capacitor rear surface 103. Although each rear surface side grounding electrode 122 is individually formed on the capacitor rear surface 103, it may be integrally formed. The rear surface side power supplying electrodes 121 are directly connected to the end faces of the plural power supplying via conductors 131 at the capacitor rear surface 103. The rear surface side grounding electrodes 122 are directly connected to the end faces of the plural grounding via conductors 132 at the capacitor rear surface 103. Thus, the power supplying electrodes 111, 112 is electrically connected to the power supplying via conductor 131 and the power supplying inner electrode layer 141. On the other hand, the grounding electrodes 112, 122 are electrically connected to the grounding via conductor 132 and the grounding inner electrode layer 142.

As shown in FIGS. 4 to 6, the electrode 111, 112, 121, 122 is comprised mainly of nickel, and the surface thereof is entirely covered with a copper plating layer (not illustrated). In the first embodiment, the electrode 111, 112, 121, 122 has a generally circular shape, as viewed in the plane direction, the diameter thereof is about 500 μm, and the minimum pitch therebetween is about 580 μm.

As shown in FIG. 1, the electrode 111, 112 provided on the capacitor main surface 102 is electrically connected to the MCM 21 through the via conductor 47, the conductor layer 42, the via conductor 43, the terminal pad 44, the solder bump 45 and the surface connection terminal 22 of the MCM 21. On the other hand, the electrode 121, 122 provided on the capacitor rear surface 103 is electrically connected to an electrode (non contact terminal) provided in a motherboard (not illustrated) through the via conductor 47, the conductor layer 42, the via conductor 43, the PGA pad 48 and the pin 49.

For example, when electric conduction is effected from the motherboard side through the electrode terminal 121, 122 to apply a voltage across the power supplying inner electrode layer 141 to the grounding inner electrode layer 142, positive charges, for example, are accumulated in the power supplying inner electrode layer 141, while negative charges, for example, are accumulated in the grounding inner electrode layer 142. As a result, the ceramic capacitor 101 functions as a capacitor. In addition, in the ceramic capacitor 101, the power supplying via conductor 131 and the grounding via conductor 132 are disposed adjacent to each other, so that the direction of current flowing through the power supplying via conductor 131 and the grounding via conductor 132 opposite to each other. As a result, reduction in the inductance component is attained.

As shown in FIG. 1, each current supplying conductor 15 formed in the conductor containing portion 14 is electrically connected to the memory chip 26 of the MCM 21 through the current supplying connection pad 19, a first connection terminal 151 provided in the component mounting region 23 of the first buildup layer 31 and the surface connection terminal 22 of the MCM 21. Each current supplying conductor 15 and the first connection terminal 151 are not a signal wiring for sending signals but are the wiring for supplying current to the memory chip 26. The first connection terminal 151 is comprised of the via conductor 47, the conductor layer 42, the via conductor 43, the terminal pad 44 and the solder bump 45.

A part of each power supplying via conductor 131 and a part of each grounding via conductor 132 are electrically connected to the microprocessor chip 24 of the MCM 21 through the main surface side power supplying electrode 111 (or the main surface side grounding electrode 112), a second connection terminal 152 in the first buildup layer 31 and the surface connection terminal 22. The second connection terminal 152 constitutes a wiring which electrically connects the ceramic capacitor 101 and the microprocessor chip 24, and is comprised of the via conductor 47, the conductor layer 42, the via conductor 43, the terminal pad 44 and the solder bump 45.

A part of each power supplying via conductor 131 and a part of each grounding via conductor 132 are electrically connected to the microprocessor chip 25 of the MCM 21 through the main surface side power supplying electrode 111 (or the main surface side grounding electrode 112), a second connection terminal 153 in the first buildup layer 31 and the surface connection terminal 22. The second connection terminal 153 constitutes a wiring which electrically connects the ceramic capacitor 101 and the microprocessor chip 25, and is comprised of the via conductor 47, the conductor layer 42, the via conductor 43, the terminal pad 44 and the solder bump 45. It is noted that the second connection terminal 153 is electrically isolated from the second connection terminal 152. The second connection terminals 152, 153 are disposed so as to sandwich the first connection terminal 151.

Next, a method for manufacturing of the wiring board 10 according to the first embodiment will be described.

In a preparatory step, a semi-finished product of the core board 11 is produced in advance with a conventionally known method.

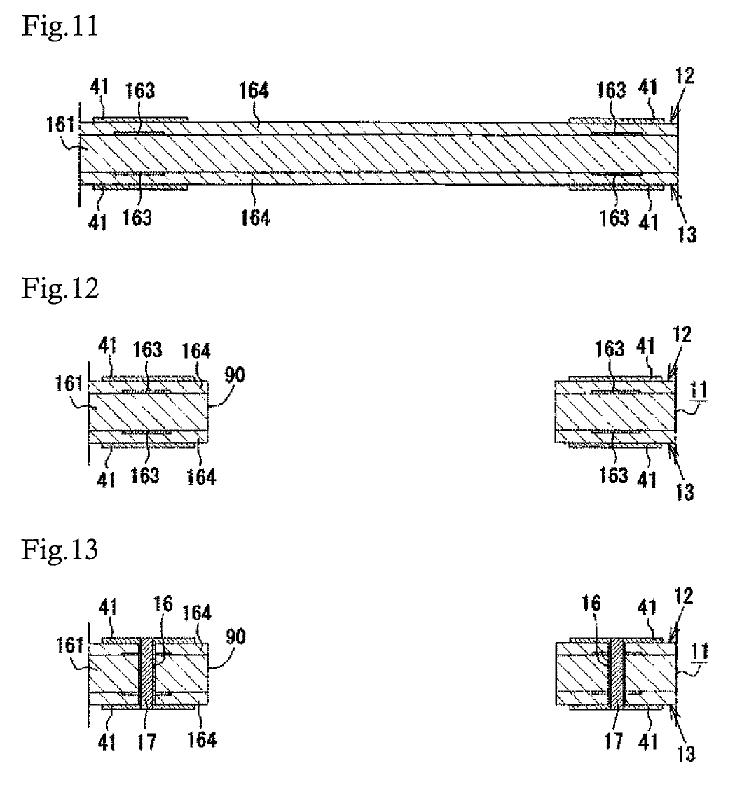

The semi-finished product of the core board 11 is produced as follows. First, a copper-clad laminated board in which a copper foil 162 is laminated on both surfaces of the substrate 161 having a size of 400 mm long×400 mm wide×0.6 mm thick is prepared (refer to FIG. 9). Next, the copper foil 162 on both surfaces of the copper-clad laminated board is subjected to etching so as to pattern a conductor layer 163 by, for example, a subtractive method (see FIG. 10). More particularly, after electroless copper plating, electrolytic copper plating is performed by using this electroless copper plating layer as a common electrode. Subsequently, a dry film is laminated on thus-plated surface and subjected to an exposure and a development to thereby form predetermined pattern. In this state, an unnecessary electrolytic copper plating layer, electroless copper plating layer and the copper foil 162 are removed by etching. Thereafter, the dry film is exfoliated. Next, after roughening the upper surface and the lower surface of the substrate 161 and the conductor layer 163, an epoxy resin film (80 micrometers in thickness) to which inorganic filler is added is laminated on the upper surface and the lower surface of the substrate 161 by thermocompression bonding to thereby form the sub-substrate 164 (refer to FIG. 11).

Next, the conductor layer 41 is pattern printed on the upper surface of the upper sub-substrate 164 and the lower surface of the lower sub-substrate 164, respectively. More particularly, after performing electroless copper plating to the upper surface of the upper sub-substrate 164 and the lower surface of the lower sub-substrate 164, etching resist is formed, and thereafter, electrolytic copper plating is performed. Further, etching resist is removed and soft etching is performed. Then, a laminated body comprised of the substrate 161 and the sub-substrate 164 is subjected to a boring step using a router to form a through hole used as the accommodation hole 90 in a predetermined position (see FIG. 12).

Further, a boring step is performed using YAG laser or carbon dioxide laser to form a plurality of through holes penetrating the core board 11 in advance. After electroless copper plating is applied to the inside of each through hole, etching resist is formed, and then electrolytic copper plating is performed. Etching resist is removed and soft etching is performed. Thereby, the through hole conductor 16 is formed in each through hole. Next, the plugging body 17 is filled in the through hole conductor 16 to complete the semi-finished product of the core board 11 (see FIG. 13). The semi-finished product of the core board 11 means a core board for producing a plurality of core boards 11 in which a plurality of regions serving later as the core boards 11 is disposed vertically and horizontally along the plane direction.

In a conductor containing portion preparation step, a semi-finished product of the conductor containing portion 14 is produced with the same method as the core board 11, and is prepared in advance. First, the first substrate 165 made of the same material as that of the substrate 161 is prepared. Next, after roughening an upper surface and a lower surface of the first substrate 165, the second substrate 166 made of the same material as that of the sub-substrate 164 is formed on the upper surface and the lower surface of the first substrate 165.

Next, the current supplying connection pad 19 is pattern printed on the upper surface of the second upper substrate 166 and the lower surface of the second lower substrate 166, respectively. More particularly, after applying electroless copper plating to the upper surface of the second upper substrate 166 and the lower surface of the second lower substrate 166, etching resist is formed, and subsequently electrolytic copper plating is applied. Thereafter, etching resist is removed and soft etching is performed.

Further, a boring step is performed using YAG laser or carbon dioxide laser to form a plurality of through holes penetrating the conductor containing portion 14 in advance. After electroless copper plating is applied to the inside of each through hole, etching resist is formed, and then electrolytic copper plating is performed. Thereafter, etching resist is removed and soft etching is performed. Thereby, the current supplying conductor 15 is formed in each through hole. Next, the plugging body 18 is filled in the current supplying conductor 16 to complete the semi-finished product of the conductor containing portion 14. The semi-finished product of the conductor containing portion 14 means a conductor containing portion for producing a plurality of conductor containing portions 14 in which a plurality of regions serving later as the conductor containing portions 14 is disposed vertically and horizontally along the plane direction.

Then, the semi-finished product of the conductor containing portion 14 is divided into individual piece parts of the conductor containing portion 14. At this time, the conductor containing portion 14 is cut so as to assume a circular shape in each conductor forming region. As a result, the individual conductor containing portions 14 are simultaneously produced.

In a capacitor preparation step, the ceramic capacitor 101 having the through hole 107 is produced in advance with a conventionally known method.

The ceramic capacitor 101 is produced as follows. A ceramic green sheets are formed, and then nickel paste for inner electrode layers is screen-printed on the green sheets and is allowed to dry. In consequence, power supplying inner electrode portions and grounding inner electrode portions, which serve as the power supplying inner electrode layers 141 and the grounding inner electrode layers 142 later, respectively, are formed. Next, the green sheets each having the power supplying inner electrode portions formed thereon and the green sheet having the grounding inner electrode portions formed thereon are alternately laminated, and as a pressing force is imparted thereto in the laminated direction of the sheets, thereby integrating the green sheets and forming a green sheet laminated body.

Furthermore, a plurality of via holes 130 are formed in the green sheet laminated body using a laser processing machine, and nickel paste for via conductors is filled in each via hole 130 using a press-fitting and filling machine (not illustrated). Next, paste for forming electrodes is printed on the upper surface of the green sheet laminated body to form the main surface side power supplying electrodes 111 and the main surface side grounding electrodes 112 so as to cover the upper end face of each conductor portion at the upper side of the green sheet laminated body. Also, the paste is printed on the lower surface of the green sheet laminated body to form the rear surface side power supplying electrodes 121 and the rear surface side grounding electrodes 122 so as to cover the lower end face of each conductor portion at the lower side of the green sheet laminated body.

Subsequently, the green sheet laminated body is dried so that a surface terminal portion may be solidified to some extent. Next, the green sheet laminated body is degreased and subjected to firing at a predetermined temperature for a predetermined time. As a result, barium titanate and nickel contained in the paste are simultaneously sintered, thereby forming the ceramic sintered body 104.

Next, the electroless copper plating (about 10 um in thickness) is applied to each electrode terminal 111, 112, 121, 122 of the ceramic sintered body 104. As a result, the copper plating layer is formed on each electrode terminal 111, 112, 121, 122, thereby completing the ceramic capacitor 101.

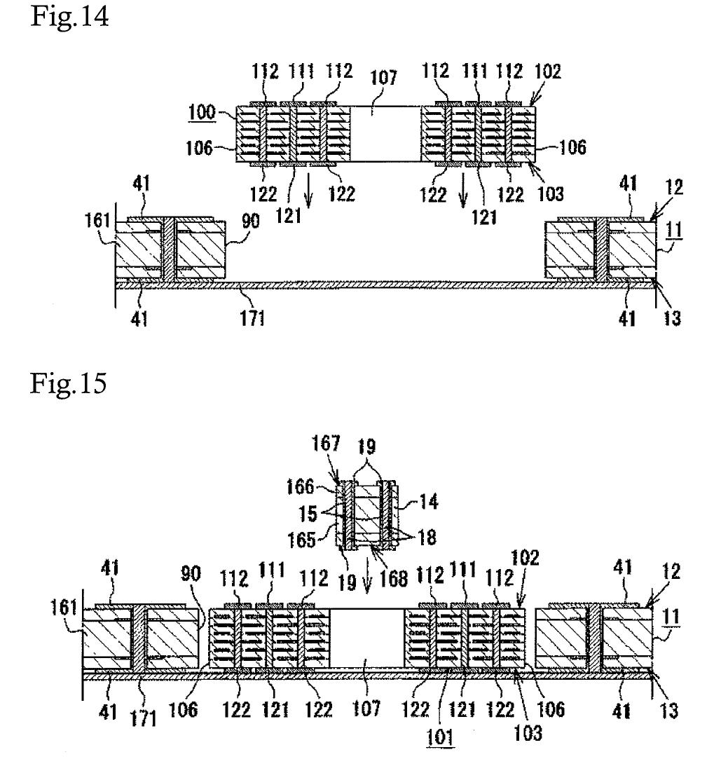

In a subsequent fixation step, the ceramic capacitors 101 is accommodated in the accommodation hole 90 using a mounting device (made by Yamaha Motor Co., Ltd.) with its capacitor main surface 102 facing the same side as the core main surface 12 (refer to FIG. 14). At this time, the lower surface 13 side opening of the accommodation hole 90 is sealed by an exfoliable adhesive tape 171. The adhesive tape 171 is supported by a support table (not illustrated). The ceramic capacitor 101 is adhered and temporarily fixed to an adhesive face of the adhesive tape 171. (refer to FIG. 15).

Further, in the fixation step, the conductor containing portion 14 is accommodated in the through hole 107 of the ceramic capacitor 101 with its main surface 167 facing the same side as the core main surface 12 (capacitor main surface 102) by a mounting device (made by Yamaha Motor Co., Ltd.) (refer to FIG. 15). Thus, the conductor containing portion 14 is disposed in the through hole 107 so as to be surrounded by the ceramic capacitor 101. The conductor containing portion 14 is adhered and temporarily fixed to an adhesive face of the adhesive tape 171.

Subsequently, a buildup layer forming step is conducted. In the buildup layer forming step, the first buildup layer 31 is formed on the core main surface 12, and the second buildup layer 32 is formed on the core rear surface 13 with the conventionally known method. More particularly, a photosensitive epoxy resin is coated on the core main surface 12 and the capacitor main surface 102, and exposure and development are performed, thereby forming the lowermost resin insulating layer 33. Alternatively, an insulating resin or a liquid crystal polymer (LCP: Liquid Crystalline Polymer) may be used instead of the photosensitive epoxy resin. Further, the gap between the inner face of the accommodation hole 90 and the capacitor side face 106 is filled with the filler 33a which is a part of the resin insulating layer 33. Then, after the heat treatment, the resin insulating layer 33 (the filler 33a) is cured, and the ceramic capacitor 101 and the conductor containing portion 14 are fixed to the core board 11. Then, a semi-finished product of the wiring board 10 is completed. At this time, the adhesive tape 171 is exfoliated.

Next, a photosensitive epoxy resin is coated on the core rear surface 13 and the capacitor rear surface 103, and performing exposure and development, thereby forming the resin insulating layer 34. Alternatively, an insulating resin or a liquid crystal polymer may be used instead of the photosensitive epoxy resin. Further, via holes (not illustrated) are formed in the predetermined positions where the via conductors 47 are to be formed by laser drilling using a YAG laser or carbon dioxide laser. More particularly, the via holes penetrating the resin insulating layer 33 are formed so as to expose the main surface side power supplying electrodes 111 and the main surface side grounding electrodes 112. Also, the via holes penetrating the resin insulating layer 34 is formed so as to expose the rear surface side power supplying electrodes 121 and the rear surface side grounding electrodes 122. Subsequently, the electrolytic copper plating is performed in accordance with the conventionally known method (e.g., semiadditive method) to thereby form the via conductors 47 inside of the via holes, as well as forming the conductor layers 42 on the resin insulating layer 33, 34 serving as the first layer.

Next, the photosensitive epoxy resin is laminated on the resin insulating layers 33, 34, and the exposure and development thereof are performed to form the resin insulating layers 35, 36 having via holes in the predetermined positions where the via conductors 43 are to be formed. Alternatively, an insulating resin or a liquid crystal polymer may be used instead of the photosensitive epoxy resin. In this case, via holes are formed in the predetermined positions where the via conductors 43 are to be formed by a laser processing machine. Then, the electrolytic copper plating is applied in accordance with the conventionally known method to form the via conductors 43 inside of the via holes, as well as forming the terminal pads 44 on the resin insulating layer 35, and the PGA pads 48 are formed on the resin insulating layer 36.

Subsequently, the photosensitive epoxy resin is coated on the resin insulating layers 35, 36, and is allowed to cure, thereby forming the solder resist 37, 38. Next, exposure and development are conducted in a state in which a predetermined mask is disposed, thereby patterning the opening portions 40, 46 in the solder resist 37, 38. Further, the solder bumps 45 are formed on the terminal pad 44, respectively, and the pins 49 are formed on the PGA pads 48. It is noted that an article in this state is a wiring board for producing a plurality of wiring boards 10 and in which a plurality of product regions serving later as the wiring boards 10 is disposed vertically and horizontally along the plane direction. Further, the wiring board for producing the plurality of wiring boards 10 is divided into each individual part, thereby simultaneously producing the plurality of wiring boards 10.

Therefore, according to the first embodiment, it is possible to obtain the following advantages.

(1) According to the wiring board 10 of the first embodiment, since the through hole 107 is formed in the ceramic capacitor 101, the conductor containing portion 14 can be smoothly disposed in the through hole 107 without dividing it into small size or reducing the size of the ceramic capacitor 101. Therefore, a high current can be supplied through the current supplying conductors 15 formed in the conductor containing portion 14 and the first connection terminal 151 to the MCM 21 mounted on the component mounting region 23 where the first connection terminal 151 is provided. Further, irrespective of the absence/presence of the conductor containing portion 14, it is possible to produce the ceramic capacitor 101 having the enlarged capacitor main surface 102, thereby being able to increase the capacity of the ceramic capacitor 101. Further, the MCM 21 mounted on the component mounting region 23 is reliably supported by the ceramic capacitor 101. Thus, since the first buildup layer 31 is unlikely to deform in the component mounting region 23, the mechanical stress imposing on the MCM 21 can be alleviated, thereby improving the reliability of wiring board 10.

(2) According to the first embodiment, the through hole 107 of the ceramic capacitor 101 assumes a circular shape in the cross section, and no angular corner exist in the through hole 107. Therefore, stress concentration on a portion (corner) of the through hole 107 due to temperature change can be alleviated, thereby preventing the occurrence of the crack in the through hole 107. Further, since it is easy to make opening area of the through hole 107 small, the capacitor main surface 102 is easily enlarged. As a result, each area of the inner electrode layer 141, 142 in each layer can be enlarged, thereby increasing the capacity of the ceramic capacitor 101. The ceramic capacitor 101 according to the first embodiment has a structure in which the through hole 107 opens at both the capacitor main surface 102 and the capacitor rear surface 103. Thus, the mechanical integrity of the ceramic capacitor 101 becomes high and the ceramic capacitor 101 is unlikely to deform, compared to the case where the through hole 107 opens at a portion of the capacitor side face 106 in addition to the capacitor main surface 102 and the capacitor rear surface 103.

(3) In the first embodiment, the current supplying conductor 15 is electrically connected to the memory chip 26, while the ceramic capacitor 101 is electrically connected to each microprocessor chip 24 and 25. Thus, even in the case where the power supply system cannot be shared between the memory chip 26 and the microprocessor chip 24, 25 because the memory chip 26 requires a higher current than that required by the microprocessor chips 24, 25, the memory chip 26 and each microprocessor chip 24, 25 can fully operate. Therefore, when adopting the structure in which the MCM 21 is mounted on the wiring board 10 as in the first embodiment, its merit can be fully utilized.

(4) Since the ceramic capacitor 101 is disposed immediately below the microprocessor chips 24, 25 in the first embodiment, the distance of the wiring connecting the ceramic capacitor 101 to the microprocessor chip 24, 25 becomes short, thereby achieving the reduction in the inductance component. Therefore, the switching noise of the microprocessor chips 24, 25 caused by the ceramic capacitor 101 can be certainly reduced, and the power supply voltage can be stabilized. Further, the noise invading between the MCM 21 and the ceramic capacitor 101 can be substantially reduced. As a result, any defects, such as malfunctions, are unlikely to occur and high reliability of the wiring board 10 can be achieved.

(5) In the first embodiment, since the filler filling the gap between the inner face of the accommodation hole 90 and the capacitor side face 106 is the filler 33a which constitutes a part of the resin insulating layer 33, it is not necessary to prepare a different material to the material of the resin insulating layer 33. Thus, because the number of materials required for manufacturing the wiring board 10 can be reduced, the wiring board 10 can be manufactured cost-effective.

The first embodiment may be modified as follows.

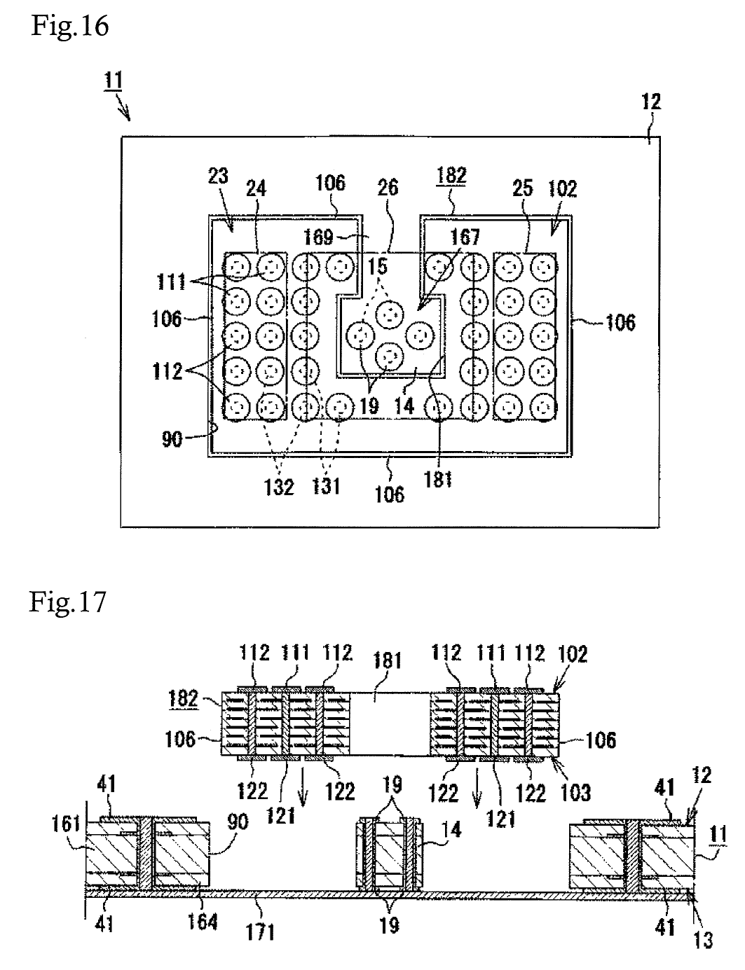

The wiring board 10 according to the first embodiment employs the ceramic capacitor 101 having the through hole 107 which assumes a circular shape (i.e., a rounded shape) in the plane section view. However, as shown in FIG. 16, a ceramic capacitor 182 having a linear-shaped through hole 181 may be used. The manufacturing process of the linear-shaped through hole is easier than that of the rounded through hole and it contributes to the reduction in the processing cost of the through hole. However, considering the occurrence of crack, the circular-shaped through hole 107 in the cross section view is preferable.

Although the conductor containing portion 14 in the first embodiment is formed as a separate body from the core board 11, it may be formed as a part of the core board 11, and comprised of a part of the substrate 161 and a part of the sub-substrate 164. In this case, the conductor containing portion 14 is connected to the core board 11 through a connecting portion 169 which is comprised of a part of the substrate 161 and a part of the sub-substrate 164 (refer to FIG. 16). It is noted that the conductor containing portion 14 may be connected to the core board 11, for example, only through the sub substrate 164.

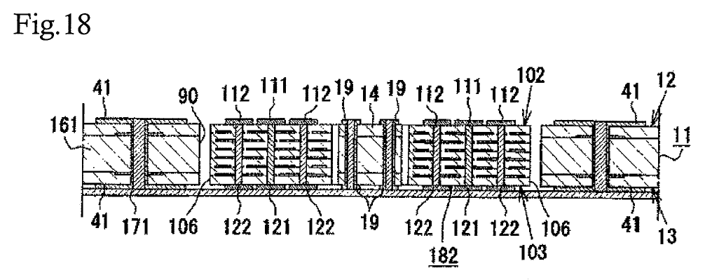

With the above composition, when the accommodation hole 90 is formed in the laminated body comprised of the substrate 161 and the sub-substrate 164 during the manufacturing process of the wiring board 10, the conductor containing portion 14 is formed in the center of the core board 11. Therefore, instead of accommodating both the ceramic capacitor 101 and the conductor containing portion 14 in the accommodation hole 90, only the ceramic capacitor 101 is accommodated therein in the fixation step (refer to FIGS. 17 and 18).

According to the first embodiment, four current supplying conductors 15 are formed in the conductor containing portion 14. However, the number of current supplying conductors 15 may be five or more, or may be three or less. When the number of current supplying conductors 15 is three or less, the diameter of the current supplying conductor, is preferably larger than the diameter of current supplying conductor 15 of the first embodiment.

According to the first embodiment, although the MCM 21 is used as an electronic component, other electronic components may be used. For example, a multi-core microprocessor in which two or more processor cores are accumulated on a chip may be used as an electronic component. With this composition, parallel processing of plural threads (tasks), which is not attainable with a single core microprocessor in which only one processor core is mounted on a chip, is feasible. As a result, this enhances the processing capacity of the entire system. Furthermore, failure resistance of the system also improves compared to that of the single core microprocessor.

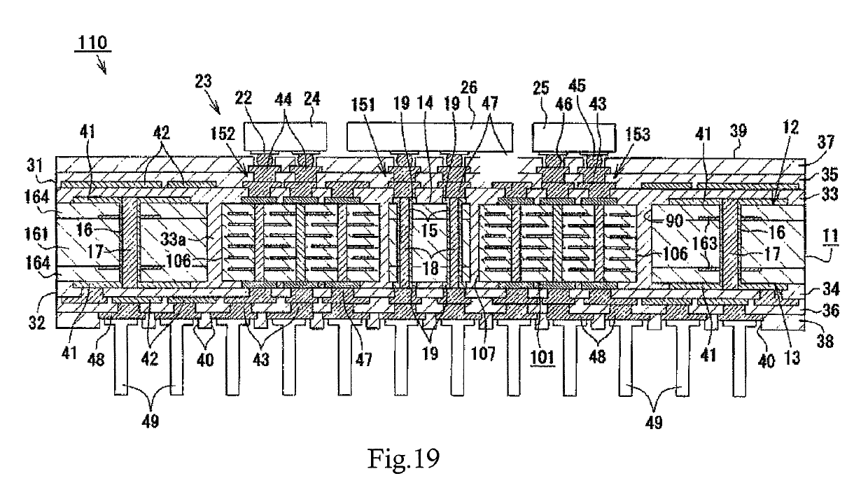

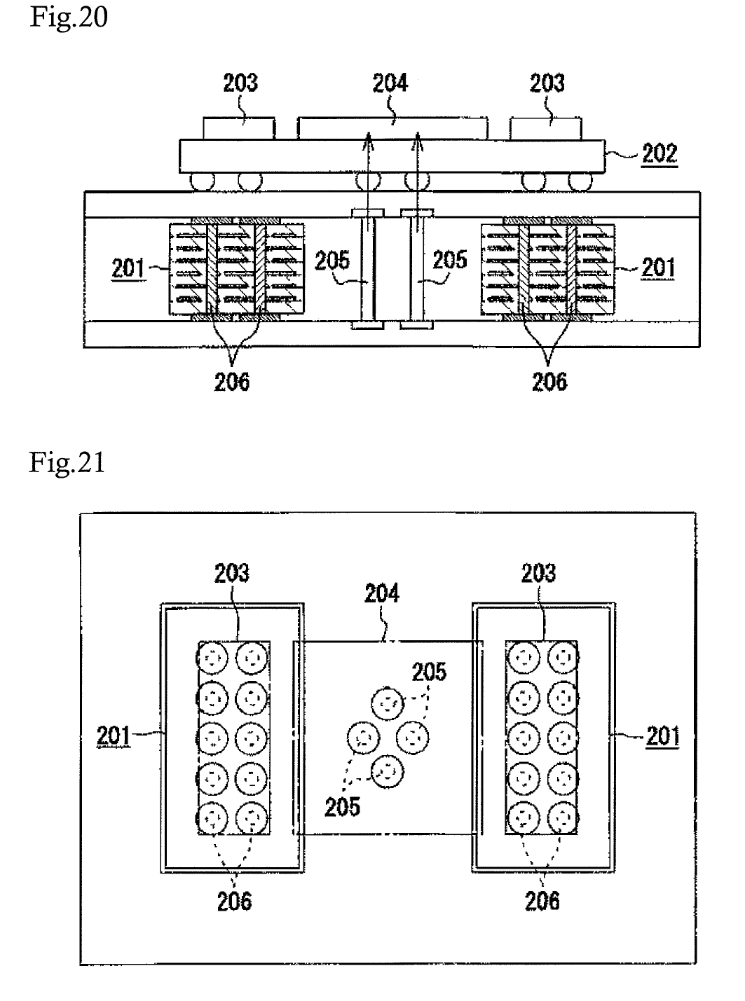

As shown in FIG. 19, the relay board 27 of the first embodiment may be omitted, and the microprocessor chips 24, 25 and the memory chip 26 may be individually used as an electronic component. That is, the surface connection terminals 22 are provided in lower surfaces of the microprocessor chips 24, 25 and the memory chip 26, respectively, so that the microprocessor chips 24, 25 and the memory chip 26 are directly mounted on the component mounting region 23.

In the first embodiment, the filler 33a which is a part of the resin insulating layer 33 is used. The filler 33a is filled in the gap between the inner face of the accommodation hole 90 and capacitor side face 106, and the gap between the inner wall of the through hole 107 of the ceramic capacitor 101 and the side face of the conductor containing portion 14. However, the above gaps may be filled with another filler other than the filler 33a. In this way, since the function of the filler 33a can be specialized in the function for fixing the ceramic capacitor 101 and the conductor containing portion 14, the reliability of the wiring board 10 can be improved.

Next, a second embodiment for carrying out a capacitor built-in wiring board according to the present invention will be described in detail with reference to the drawings. In the following description, same explanations as those of the wiring board 10 will be omitted, and only point differently from those of the wiring board 10 will be explained.

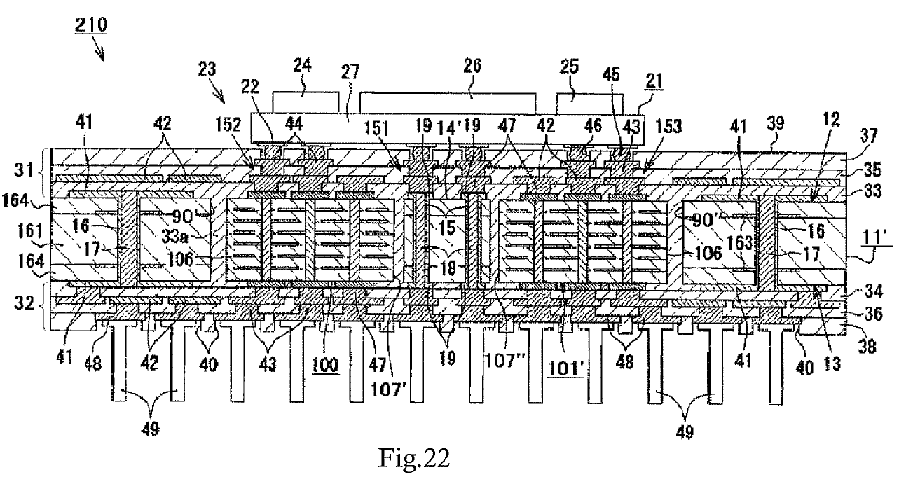

As shown in FIGS. 22, 23 and 24, a conductor containing portion 14′ is formed in the center of a core board 11′. The conductor containing portion 14′ according to the second embodiment has a generally square shape as seen from the plane view with the size of 3.0 mm long×3.0 mm wide×1.0 mm thick. The conductor containing portion 14′ is a part of the core board 11′ and is comprised of a part of the substrate 161 and a part of the sub-substrate 164. Further, the conductor containing portion 14′ includes a plurality of copper-made current supplying conductors 15 (four in the second embodiment) is formed so as to penetrated the core main surface 12 and the core rear surface 13. The current supplying conductor 15 is a through hole conductor for electrically connecting the core main surface 12 and the core rear surface 13 of the core board 11. The inside of the current supplying conductor 15 is filled with the plugging body 18, such as an epoxy resin.

The current supplying connection pads 19 made of copper are formed so as to project from the main surface (core main surface 13) and the rear surface (core rear surface 12) of the conductor containing portion 14′. The current supplying connection pad 19 provided on the main surface of the conductor containing portion 14′ is directly connected to an end of the current supplying conductor 15 at the main surface of the conductor containing portion 14′. Further, the current supplying connection pad 19 provided on the rear surface of the conductor containing portion 14′ is directly connected to an end of the current supplying conductor 15 at the rear surface of the conductor containing portion 14′. The current supplying connection pad 19 has a disc-like shape, and an axis of the current supplying connection pad 19 is coaxially formed with the center of the current supplying conductor 15.

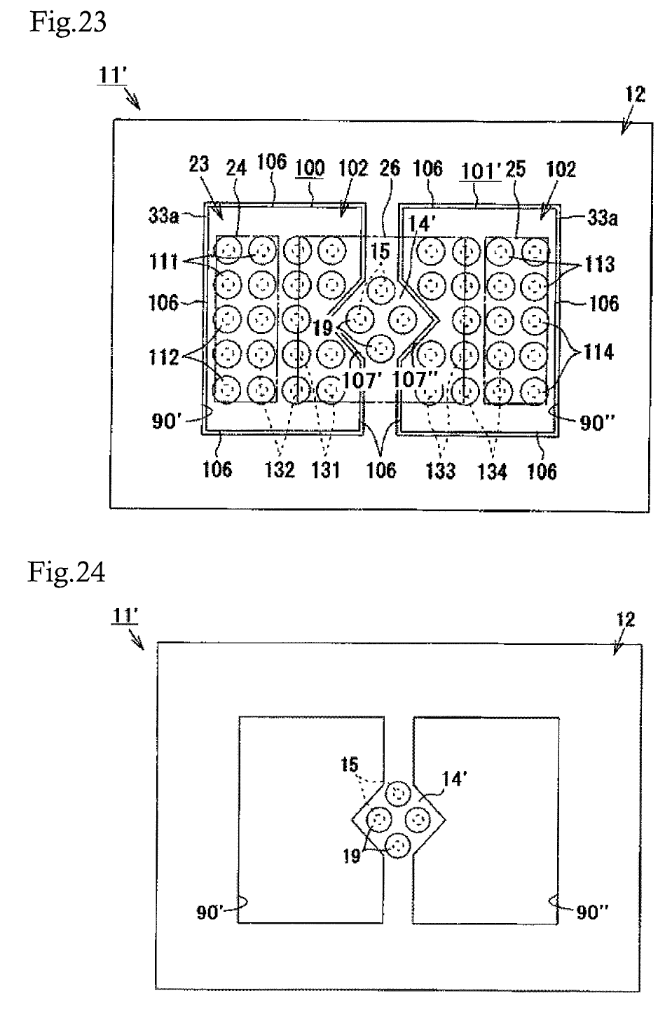

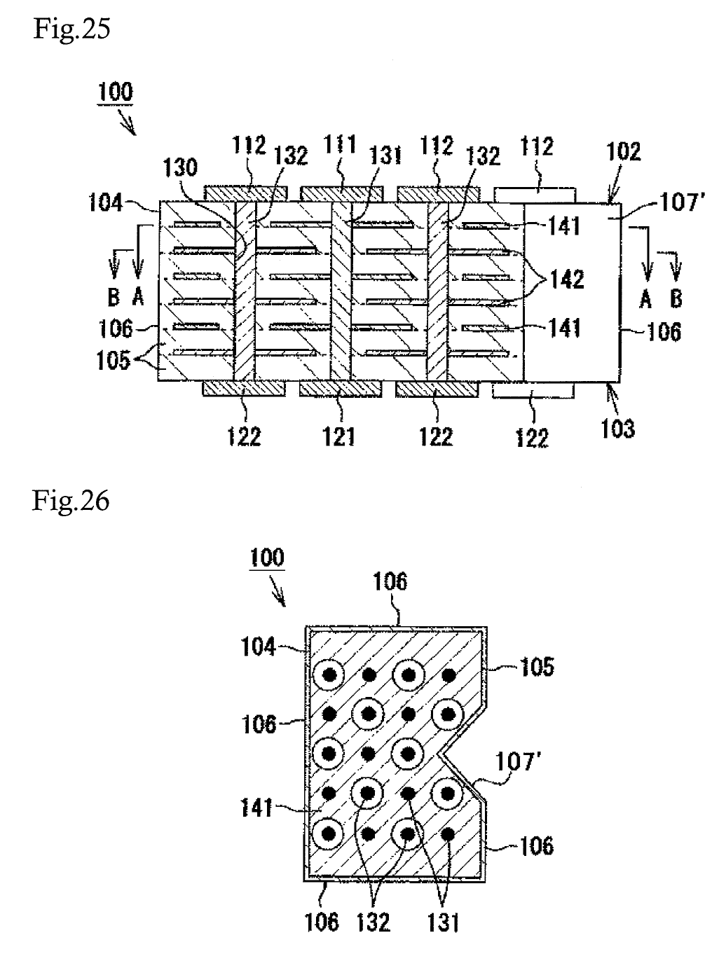

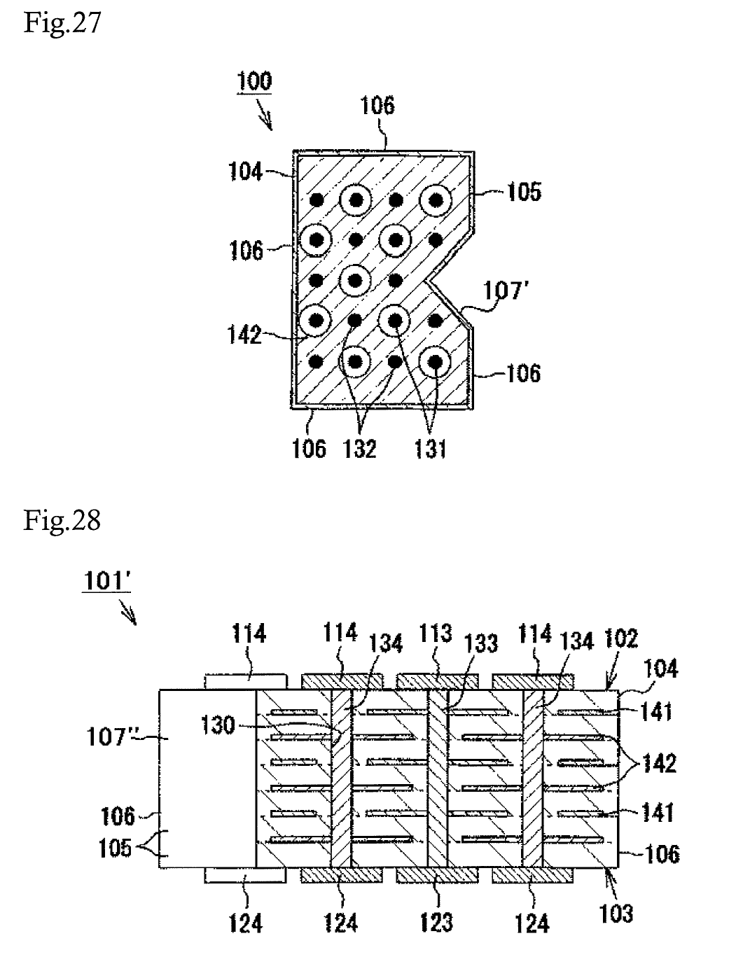

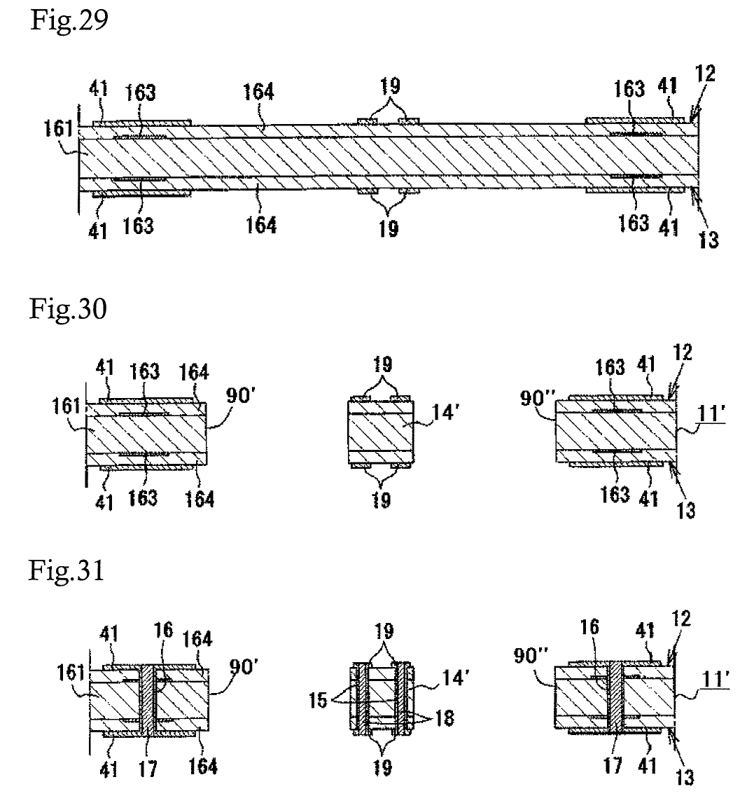

Further, the core board 11′ has two accommodation holes 90′, 90″ opening at the center of both core main surface 12 and the core rear surface 13 so as to sandwich the conductor containing portion 14′. That is, each accommodation hole 90′, 90″ are penetration holes and assumes a generally rectangular shape as viewed in the plane view (a part of the accommodation hole is notched so as to avoid the conductor containing portion 14′). Two ceramic capacitors 100, 101′ as shown in FIGS. 25 to 28 are accommodated in each accommodation hole 90′, 90″, respectively, in an embedded state. In addition, the ceramic capacitor 100, 101′ is accommodated with its capacitor main surface 102 facing the same side as the core main surface 12 of the core board 11′. The ceramic capacitor 100, 101′ in the second embodiment assumes a plate-like shape with the size of 25.0 mm long×10.0 mm wide (maximum value)×0.8 mm thick. In the core board 11′, the ceramic capacitor 100, 101′ is disposed in a region immediately below the component mounting area 23. The dimension of the component mounting area 23 (an area of the region where the surface connection terminals 22 of the MCM are formed on) is equal to the total area of the capacitor main surface 102 of the ceramic capacitor 100 and the capacitor main surface 102 of the ceramic capacitor 101′. Thus, the component mounting area 23, as viewed in the thicknesswise direction of the ceramic capacitor 100, 101′, is disposed within the capacitor surface 102 of the ceramic capacitor 100, 101′. More particularly, as shown in FIG. 23, the microprocessor chip 24 of the MCM 21 is disposed on the capacitor main surface 102 of the ceramic capacitor 100 and the microprocessor chip 25 of the MCM 21 are disposed on the capacitor main surface 102 of the ceramic capacitor 101′. Further, the memory chip 26 of the MCM 21 is disposed in an upward direction of the main surface of the conductor containing portion 14′ so that the memory chip 26 covers the capacitor main surface 102 of the ceramic capacitor 100 and the capacitor main surface 102 of the ceramic capacitor 101′. It is noted that the ceramic capacitor 101′ has the same composition as that of the ceramic capacitor 100 and is shaped like an inverted ceramic capacitor 100.

As shown in FIGS. 22 and 23, a gap between an inner face of the accommodation hole 90′, 90″ and a capacitor side face 106 of the ceramic capacitor 100, 101′is filled with a filler 33a which is a part of the lowermost resin insulating layer 33 attaching to the core main surface 12. The filler 33a has a function of fixing the ceramic capacitor 100, 101′ and the conductor containing portion 14′ to the core board 11′. The ceramic capacitor 100, 101′ includes a tapered portion at each four corners thereof with a radius of 0.55 mm or more (0.6 mm in the second embodiment). As a result, when the filler 33a deforms due to a temperature variation, the stress concentration to the corners of ceramic capacitor 100, 101′ can be alleviated, thereby preventing the occurrence of cracks in the filler 33a.

As shown in FIGS. 25 to 28, each ceramic capacitor 100, 101′ assumes an atypical plate-like shape in which one capacitor side face 106 has a generally “V”-shape notch 107′, 107″ as viewed in the plane view. Each ceramic capacitor 100, 101′ is accommodated in the state where the notches 107′, 107″ face the conductor containing portion 14′, respectively. Thus, the notch 107′ of the ceramic capacitor 100 and the notch 107″ of the ceramic capacitor 101′ are opposed to each other.

The ceramic capacitor 100, 101′ of the second embodiment is so-called “a via array type ceramic capacitor”. A ceramic sintered body 104 comprising the ceramic capacitor 100, 101′ has the capacitor main surface 102 (upper surface in FIG. 22), the capacitor rear surface 103 (lower surface in FIG. 22) and four capacitor side faces 106 (right and left side faces in FIG. 22).

In the ceramic capacitor 100 shown in FIGS. 25-27, although via conductors in the capacitor 131, 132 are illustrated in the array of 5 rows (longitude)×4 rows (lateral) (or 3 rows in lateral) in the second embodiment for the explanation's sake, a greater number of rows are actually present.

Similarly, in the ceramic capacitor 101′ shown in FIG. 28, although the via conductor in the capacitor 133, 134 are illustrated in the array of 5 rows (longitude)×4 rows (lateral) (or 3 rows in lateral) in the second embodiment, a greater number of rows are actually present.

Next, a method for manufacturing a wiring board 210 according to the second embodiment will be described. The explanation of the same manufacturing steps as those in the first embodiment will be omitted.

In the second embodiment, the conductor layer 41 and the current supplying connection pad 19 are pattern printed on the upper surface of the upper sub-substrate 164 and the lower surface of the lower sub-substrate 164, respectively. This process differs from the first embodiment. More particularly, after performing electroless copper plating to the upper surface of the upper sub-substrate 164 and the lower surface of the lower sub-substrate 164, etching resist is formed, and thereafter, electrolytic copper plating is performed. Further, etching resist is removed and soft etching is performed. Then, a laminated body comprised of the substrate 161 and the sub-substrate 164 is subjected to a boring step using a router to form a through hole used as the accommodation hole 90′, 90″ in a predetermined positions (see FIG. 30). It is noted that the conductor containing portion 14′ is formed in the center of the core board 11′ at this time.

Further, a boring step is performed using YAG laser or carbon dioxide laser to form a plurality of through holes penetrating the core board 11′ (and the conductor containing portion 14′) in advance. After electroless copper plating is applied to the inside of each through hole, etching resist is formed, and then electrolytic copper plating is performed. Etching resist is removed and soft etching is performed. Thereby, the through hole conductors 16 and the current supplying conductors 15 are formed in the through holes. Next, the plugging body 17 is filled in the through hole conductors 16 and the plugging body 18 is filled in the current supplying conductor 15, thereby completing the semi-finished product of the core board 11′ (see FIG. 31). The semi-finished product of the core board 11′ means a core board for producing a plurality of core boards 11′ and in which a plurality of regions serving later as the core board 11′ is disposed vertically and horizontally along the plane direction.

In a capacitor preparation step, the ceramic capacitors 100, 101′ having the notches 107′, 107″ are produced in advance with the same method as the first embodiment.

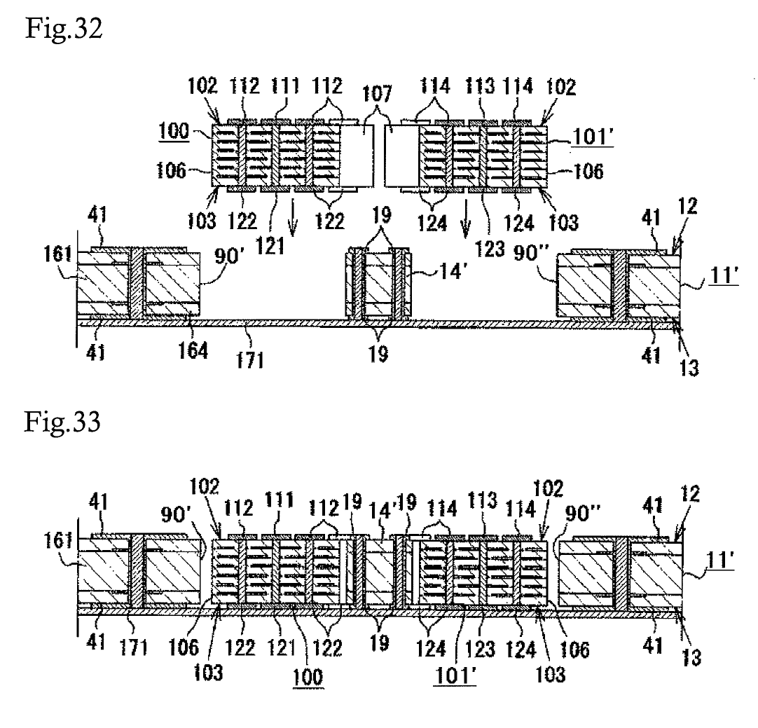

In a fixation step, the ceramic capacitors 100, 101′ are accommodated in the accommodation hole 90′, 90″ with its capacitor main surface 102 facing the same side as the core main surface 12 and the notches 107′, 107″ are opposed to each other (refer to FIG. 32).

Therefore, according to the second embodiment, it is possible to obtain the following advantages.

(1) According to the wiring board 210 of the second embodiment, a high current can be fed to the MCM 21 mounted on the component mounting region 23 where the first connection terminal 151 is provided through the current supplying conductor 15 and the first connection terminal 151. Since the plurality of ceramic capacitors 100, 101′ are accommodated in the accommodation holes 90′ and 90″, respectively, so that the notches 107′, 107″ thereof face the conductor containing portion 14′, the ceramic capacitors 100, 101′ are not necessarily disposed apart from each other with avoiding the conductor containing portion 14′. Thus, irrespective of the absence/presence of the conductor containing portion 14′, it is possible to produce the ceramic capacitors 100, 101′ having the enlarged capacitor main surface 102, thereby being able to increase the capacity of the ceramic capacitors 100, 101′. Further, the MCM 21 mounted on the component mounting region 23 is reliably supported by the ceramic capacitors 100, 101′. Thus, since the first buildup layer 31 is unlikely to deform in the component mounting region 23, the mechanical stress imposing on the MCM 21 can be alleviated, thereby improving the reliability of wiring board 210.

(2) Further, the current supplying conductor 15 is electrically connected to the memory chip 26, while the ceramic capacitors 100, 101′ are electrically connected to the microprocessor chip 24 and 25, respectively. Thus, even in the case where the power supply system cannot be shared between the memory chip 26 and the microprocessor chips 24, 25 because the memory chip 26 requires a higher current than that required by the microprocessor chips 24, 25, the memory chip 26 and each microprocessor chip 24, 25 can fully operate. Therefore, when adopting the structure in which the MCM 21 is mounted on the wiring board 210 as in the second embodiment, its merit can be fully utilized.

(3) Since the ceramic capacitor 100 is disposed immediately below the microprocessor chip 24, the distance of the wiring connecting the ceramic capacitor 100 to the microprocessor chip 24 becomes short, thereby achieving the reduction in the inductance component. Similarly, since the ceramic capacitor 101′ is disposed immediately below the microprocessor chip 25, the distance of the wiring connecting the ceramic capacitor 101′ to the microprocessor chip 25 becomes short, thereby achieving the reduction in the inductance component. Therefore, the switching noise of the microprocessor chip 24 caused by the ceramic capacitor 100 and the switching noise of the microprocessor chip 25 caused by the ceramic capacitor 101′ can be certainly reduced, thereby stabilizing the power supply voltage. Further, the noise invading between the MCM 21 and the ceramic capacitors 100, 101′ can be substantially reduced. As a result, any defects, such as malfunctions, are unlikely to occur and a high reliability of the wiring board 210 can be achieved.

The second embodiment may be modified as follows.

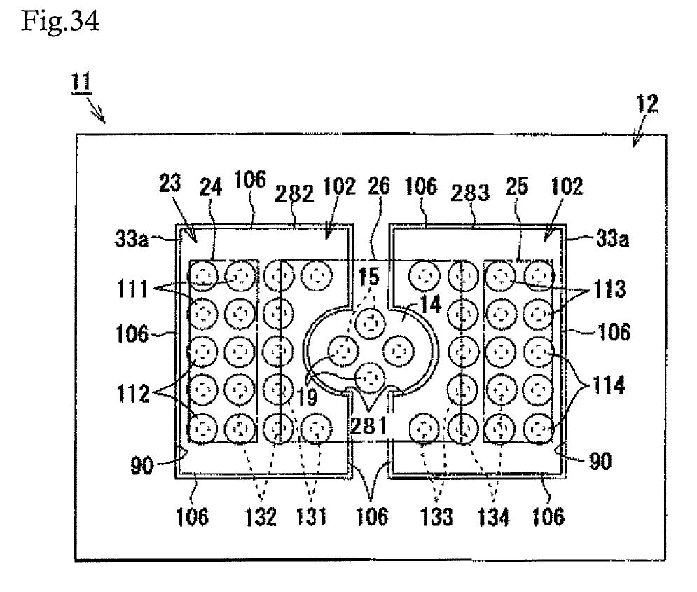

In the wiring board 210 of the second embodiment, the ceramic capacitors 100, 101′ in which each capacitor side face 106 thereof has the generally “V”-shaped notch 107′, 107″, as viewed in the plane view, are employed. However, as shown in FIG. 34, ceramic capacitors 282, 283 in which each capacitor side face 106 thereof has generally “U”-shaped notch 281, as viewed in the plane view, may be employed.

### DESCRIPTION OF REFERENCE NUMERALS

10, 210: capacitor built-in wiring board (wiring board)

11, 11′: core board

12: core main surface

13: core rear surface

14, 14′: conductor containing portion

15: current supplying conductor

19: current supplying connection pad

21: multi-chip module (MCM) serving as an electronic component

23: component mounting region

24, 25: microprocessor chip serving as an arithmetic circuit portion

26: memory chip serving as a shared circuit portion

31: first buildup layer serving as a laminated wiring portion

33, 35: resin insulating layer serving as an interlayer insulating layer

39: surface of a laminated wiring portion

42: conductor layer

90, 90′, 90″: accommodation hole

101, 182: ceramic capacitor serving as a capacitor

102: capacitor main surface

103: capacitor rear surface

107, 107′, 107″, 181: through hole

131: power supplying via conductor serving as a via conductor in the capacitor

132: grounding via conductor serving as a via conductor in the capacitor

151: first connection terminal

152, 153: second connection terminals

What is claimed is:

1. A capacitor built-in wiring board, comprising:
a core board including a core main surface, a core rear surface and an accommodation hole opening at least at the core main surface;
a capacitor including a capacitor main surface, a capacitor rear surface and a through hole penetrating the capacitor main surface and the capacitor rear surface, said capacitor having a plate-like shape and being accommodated in the accommodation hole with said capacitor main surface facing the same side as the core main surface;
a conductor containing portion including current supplying conductors electrically connecting the core main surface and the core rear surface, said conductor containing portion being accommodated in the through hole of the capacitor so as to be surrounded by the capacitor;
a laminated wiring portion having a laminated structure in which interlayer insulating layers and conductor layers are alternately laminated on the core main surface, and including a component mounting region for mounting an electronic component;
a first connection terminal being electrically connected to the current supplying conductors and being disposed in the component mounting region; and
a plurality of second connection terminals being disposed in the component mounting region so as to sandwich the first connection terminal therebetween.

2. A capacitor built-in wiring board according to claim 1,
wherein the plurality of second connection terminals are electrically connected to a plurality of arithmetic circuit portions, respectively, provided in the electronic components,
wherein the first connection terminal is shared by the plurality of arithmetic circuit portions, and is electrically connected to a shared circuit portion, which requires a larger current supply than a current supply required by the plurality of arithmetic circuit portions.

3. A capacitor built-in wiring board according to claim 2,
wherein the capacitor is a via array type ceramic capacitor having a plurality of via conductors in the capacitor.

4. A capacitor built-in wiring board according to claim 3,
wherein the current supplying conductor is made of a metal material having higher conductivity than that of the plurality of via conductors in the capacitor.

5. A capacitor built-in wiring board according to claim 1,
wherein a current supplying connection pad having a larger diameter than that of the current supplying conductor is provided on an end of the current supplying conductor.

6. A capacitor built-in wiring board according to claim 1,
wherein the conductor containing portion is formed as a separate body from the core board.

7. A capacitor built-in wiring board according to claim 6,
wherein the through hole assumes a circular shape in a cross sectional view.

8. A capacitor built-in wiring board according to claim 1,
wherein the conductor containing portion is a part of the core board.

9. A capacitor built-in wiring board according to claim 1,
wherein the through hole and the conductor containing portion are disposed in a center of the core board, and assume a shape having no angular corner, viewed in plan.

10. A capacitor built-in wiring board according to claim 1,
wherein the conductor containing portion includes no signal wiring therein.

11. A capacitor built-in wiring board according to claim 1,
wherein the capacitor is a via array type capacitor having a structure in which a plurality of inner electrode layers are laminated by sandwiching a dielectric layer therebetween, and comprising:
a plurality of via conductors in the capacitor connected to the plural inner electrode layers; and a plurality of surface electrodes connected to at least end portions of the via conductors in the capacitor at the capacitor main surface,
wherein the plurality of via conductors in the capacitor are disposed in a form of an array as a whole.

12. A capacitor built-in wiring board, comprising:
a core board including a core main surface, a core rear surface, a conductor containing portion including current supplying conductors electrically connecting the core main surface and the core rear surface, and a plurality of accommodation holes opening at least at the core main surface and disposed so as to sandwich the conductor containing portion;
a plurality of capacitors each including a capacitor main surface, a capacitor rear surface and a capacitor side face, each capacitor having a plate-like shape with a notch in the capacitor side face and being accommodated in the plurality of accommodation holes with the notch facing the conductor containing portion; and
a laminated wiring portion having a laminated structure in which interlayer insulating layers and conductor layers are alternately laminated on the core main surface, and including a component mounting region for mounting an electronic component;
a first connection terminal being electrically connected to the current supplying conductors and being disposed in the component mounting region, and
a plurality of second connection terminals being disposed in the component mounting region so as to sandwich the first connection terminal.

13. A capacitor built-in wiring board according to claim 12,
wherein the plurality of second connection terminals are electrically connected to a plurality of arithmetic circuit portions, respectively, provided in the electronic components,
wherein the first connection terminal is shared by the plurality of arithmetic circuit portions, and is electrically connected to a shared circuit portion, which requires a larger current supply than a current supply required by the plurality of arithmetic circuit portions.

14. A capacitor built-in wiring board according to claim 12,
wherein the capacitor is a via array type ceramic capacitor having a plurality of via conductors in the capacitor.

15. A capacitor built-in wiring board according to claim 14,
wherein the current supplying conductor is made of a metal material having higher conductivity than that of the plurality of via conductors in the capacitor.

16. A capacitor built-in wiring board according to claim 12,
wherein a current supplying connection pad having a larger diameter than that of the current supplying conductor is provided in an end of the current supplying conductor.

17. A capacitor built-in wiring board according to claim 12,
wherein the conductor containing portion includes no signal wiring therein.

18. A capacitor built-in wiring board according to claim 12,
wherein the capacitor is a via array type capacitor having a structure in which a plurality of inner electrode layers are laminated by sandwiching a dielectric layer therebetween, and comprising:
a plurality of via conductors in the capacitor connected to the plural inner electrode layers; and a plurality of surface electrodes connected to at least end portions of the via conductors in the capacitor at the capacitor main surface,
wherein the plurality of via conductors in the capacitor are disposed in a form of an array as a whole.

19. A capacitor built-in wiring board according to claim 1,
wherein the capacitor is a via array type ceramic capacitor having a plurality of via conductors in the capacitor.

20. A capacitor built-in wiring board according to claim 19,
wherein the current supplying conductor is made of a metal material having higher conductivity than that of the plurality of via conductors in the capacitor.
